(19) United States
(12) Patent Application Publication
(10) Pub. No.: US 2026/0006853 A1
(43) Pub. Date: Jan. 1, 2026

(54) SEMICONDUCTOR DEVICE

(71) Applicants: Japan Display Inc., Tokyo (JP); IDEMITSU KOSAN CO., LTD., Tokyo (JP)

(72) Inventors: Hajime WATAKABE, Tokyo (JP); Masashi TSUBUKU, Tokyo (JP); Toshinari SASAKI, Tokyo (JP); Takaya TAMARU, Tokyo (JP); Marina MOCHIZUKI, Tokyo (JP); Ryo ONODERA, Tokyo (JP); Masahiro WATABE, Tokyo (JP)

(73) Assignees: Japan Display Inc., Tokyo (JP); IDEMITSU KOSAN CO., LTD., Tokyo (JP)

(21) Appl. No.: 19/321,476

(22) Filed: Sep. 8, 2025

Related U.S. Application Data
(63) Continuation of application No. PCT/JP2024/007690, filed on Mar. 1, 2024.

(30) Foreign Application Priority Data
Mar. 16, 2023 (JP) 2023-042352

(51) Int. Cl. H10D 30/67

(52) U.S. Cl. CPC H10D 30/6757; H10D 30/6734; H10D 30/6736; H10D 30/6755

(57) ABSTRACT

A semiconductor device including a transistor, the transistor includes a first gate electrode, a first gate insulating film provided on the first gate electrode, an oxide semiconductor layer provided on the first gate insulating film, overlapping the first gate electrode, and having a polycrystalline structure, a second gate insulating film provided on the oxide semiconductor layer, and a second gate electrode provided on the second gate insulating film and overlapping the first gate electrode, wherein the first gate electrode has a first region and a second region, the first region overlaps the oxide semiconductor layer and protrudes in a first direction from the second gate electrode in a plan view, and the second region overlaps the second gate electrode and protrudes in a second direction that intersects the first direction from the oxide semiconductor layer in a plan view.

### CROSS-REFERENCE TO RELATED APPLICATIONS

This application is a Continuation of International Patent Application No. PCT/JP2024/007690, filed on Mar. 1, 2024, which claims the benefit of priority to Japanese Patent Application No. 2023-042352, filed on Mar. 16, 2023, the entire contents of each are incorporated herein by reference.

### FIELD

An embodiment of the present invention relates to a semiconductor device and a method for manufacturing the semiconductor device.

### BACKGROUND

In recent years, instead of amorphous silicon, low-temperature polysilicon, and single-crystal silicon, a semiconductor device using an oxide semiconductor as a channel has been developed (for example, Japanese laid-open patent publication No. 2021-141338). The field-effect mobility of a thin film transistor including a conventional oxide semiconductor layer is not so large even when an oxide semiconductor layer having crystallinity is used. Therefore, a semiconductor device in which crystalline silicon is used as a transistor that requires high-speed operation, and an oxide semiconductor is used as a transistor that requires low off-state current has been studied (for example, Japanese laid-open patent publication No. 2013-008946 and Japanese laid-open patent publication No. 2011-142621).

### SUMMARY

A semiconductor device including a transistor, the transistor includes a first gate electrode, a first gate insulating film provided on the first gate electrode, an oxide semiconductor layer provided on the first gate insulating film, overlapping the first gate electrode, and having a polycrystalline structure, a second gate insulating film provided on the oxide semiconductor layer, and a second gate electrode provided on the second gate insulating film and overlapping the first gate electrode, wherein the first gate electrode has a first region and a second region, the first region overlaps the oxide semiconductor layer and protrudes in a first direction from the second gate electrode in a plan view, and the second region overlaps the second gate electrode and protrudes in a second direction that intersects the first direction from the oxide semiconductor layer in a plan view.

### BRIEF DESCRIPTION OF DRAWINGS

FIG. 1 is a plan view showing an overview of a semiconductor device according to an embodiment of the present invention.

FIG. 2 is a cross-sectional view showing an overview of a semiconductor device according to an embodiment of the present invention.

FIG. 3 is a sequence diagram showing a method for manufacturing a semiconductor device according to an embodiment of the present invention.

FIG. 4 is a cross-sectional view showing a method for manufacturing a semiconductor device according to an embodiment of the present invention.

FIG. 5 is a cross-sectional view showing a method for manufacturing a semiconductor device according to an embodiment of the present invention.

FIG. 6 is a cross-sectional view showing a method for manufacturing a semiconductor device according to an embodiment of the present invention.

FIG. 7 is a cross-sectional view showing a method for manufacturing a semiconductor device according to an embodiment of the present invention.

FIG. 8 is a cross-sectional view showing a method for manufacturing a semiconductor device according to an embodiment of the present invention.

FIG. 9 is a cross-sectional view showing a method for manufacturing a semiconductor device according to an embodiment of the present invention.

FIG. 10 is a cross-sectional view showing a method for manufacturing a semiconductor device according to an embodiment of the present invention.

FIG. 11 is a plan view showing an overview of a semiconductor device according to an embodiment of the present invention.

FIG. 12 is a cross-sectional view showing an overview of a semiconductor device according to an embodiment of the present invention.

FIG. 13 is a sequence diagram showing a method for manufacturing a semiconductor device according to an embodiment of the present invention.

FIG. 14 is a cross-sectional view showing a method for manufacturing a semiconductor device according to an embodiment of the present invention.

FIG. 15 is a cross-sectional view showing a method for manufacturing a semiconductor device according to an embodiment of the present invention.

FIG. 16 is a cross-sectional view showing a method for manufacturing a semiconductor device according to an embodiment of the present invention.

FIG. 17 is a cross-sectional view showing a method for manufacturing a semiconductor device according to an embodiment of the present invention.

FIG. 18 is a plan view showing an overview of a display device according to an embodiment of the present invention.

FIG. 19 is a block diagram showing a circuit configuration of a display device according to an embodiment of the present invention.

FIG. 20 is a circuit diagram showing a pixel circuit of a display device according to an embodiment of the present invention.

FIG. 21 is a cross-sectional view showing an overview of a display device according to an embodiment of the present invention.

FIG. 22 is a plan view of a pixel electrode and a common electrode of a display device according to an embodiment of the present invention.

FIG. 23 is a circuit diagram showing a pixel circuit of a display device according to an embodiment of the present invention.

FIG. 24 is a cross-sectional view showing an overview of a display device according to an embodiment of the present invention.

FIG. 25 is a graph representing the results of a reliability test.

FIG. 26 is a graph representing the results of a reliability test.

### DESCRIPTION OF EMBODIMENTS

In a top-gate transistor, a source region and a drain region are formed in an oxide semiconductor layer by performing an ion-implantation using the top gate as a mask. Depending on a channel length of the transistor and a width of a back gate, the properties of the transistor tends to deteriorate easily due to a reliability test by applying a strong electric field not only to a channel region of the transistor but also to a junction between the channel region and the source region and a junction between the channel region and the drain region. For example, a threshold voltage of the transistor may shift in the negative direction.

An object of an embodiment of the present invention is to suppress a threshold variation of a transistor in a semiconductor device and improve reliability.

Hereinafter, embodiments of the present invention will be described with reference to the drawings. The following disclosure is merely an example. A configuration that can be easily conceived by a person skilled in the art by appropriately changing the configuration of the embodiment while keeping the gist of the invention is naturally included in the scope of the present invention. In order to make the description clearer, the drawings may schematically show the widths, thicknesses, shapes, and the like of the respective portions in comparison with the actual embodiments. However, the illustrated shapes are merely examples, and do not limit the interpretation of the present invention. In the present specification and the drawings, the same reference signs are given to elements similar to those described above with respect to the above-described drawings, and detailed description thereof may be omitted as appropriate.

The term “semiconductor device” refers to any device that can function by utilizing semiconductor properties. A transistor and a semiconductor circuit are one form of a semiconductor device. For example, the semiconductor device described later may be an integrated circuit (IC) such as a display device or a micro-processing unit (MPU), or a transistor used in a memory circuit.

The term “display device” refers to a structure that displays an image using an electro-optical layer. For example, the term “display device” may refer to a display panel that includes the electro-optical layer, or may refer to a structure with other optical members (e.g., polarized member, backlight, touch panel, etc.) attached to a display cell. The term “electro-optical layer” may include a liquid crystal layer, an electroluminescent (EL) layer, an electrochromic (EC) layer, an electrophoretic layer, unless there is no technical contradiction. Therefore, although a liquid crystal display device including a liquid crystal layer and an organic EL display device including an organic EL layer are exemplified as the display device, the structure according to the embodiment can be applied to a display device including other electro-optical layers described above.

In the embodiments of the present invention, a direction from a substrate toward an oxide semiconductor layer is referred to as “on” or “above”. Conversely, a direction from the oxide semiconductor layer toward the substrate is referred to as “under” or “below”. As described above, for convenience of explanation, although the phrase “above” or “below” is used to describe, for example, the substrate and the oxide semiconductor layer may be arranged so that the vertical relationship is opposite to that shown in the drawings. In the following explanation, for example, the expression “an oxide semiconductor layer on a substrate” merely describes the vertical relationship between the substrate and the oxide semiconductor layer as described above, and another member may be arranged between the substrate and the oxide semiconductor layer. The “above” or “below” means a stacking order in a structure in which a plurality of layers is stacked, and may be a positional relationship in which the transistor and a pixel electrode do not overlap each other in a plan view when expressed as the pixel electrode above the transistor. On the other hand, when expressed as the pixel electrode vertically above the transistor, it means a positional relationship in which the transistor and the pixel electrode overlap each other in a plan view. In addition, the term “plan view” means a view from a direction perpendicular to a surface of the substrate.

In the present specification and the like, the term “film” and the term “layer” may be interchanged. Further, in the present specification and the like, a plurality of oxide semiconductor layers formed of an oxide semiconductor film may be described separately using “−1” and “−2”. In addition, a plurality of conductive layers and electrodes formed from a conductive film may be described in a similar manner.

Further, in the present specification and the like, ordinal numbers are used to distinguish between components, member, parts, positions, directions, and the like, and do not indicate order or priorities.

Furthermore, in the present specification, the expressions “α includes A, B, or C,” “a includes any of A, B, and C,” and “α includes one selected from a group consisting of A, B, and C” do not exclude the case where α includes a plurality of combinations of A to C unless otherwise specified. Furthermore, these expressions do not exclude the case where α includes other elements.

In addition, the following embodiments can be combined with each other as long as there is no technical contradiction.

### First Embodiment

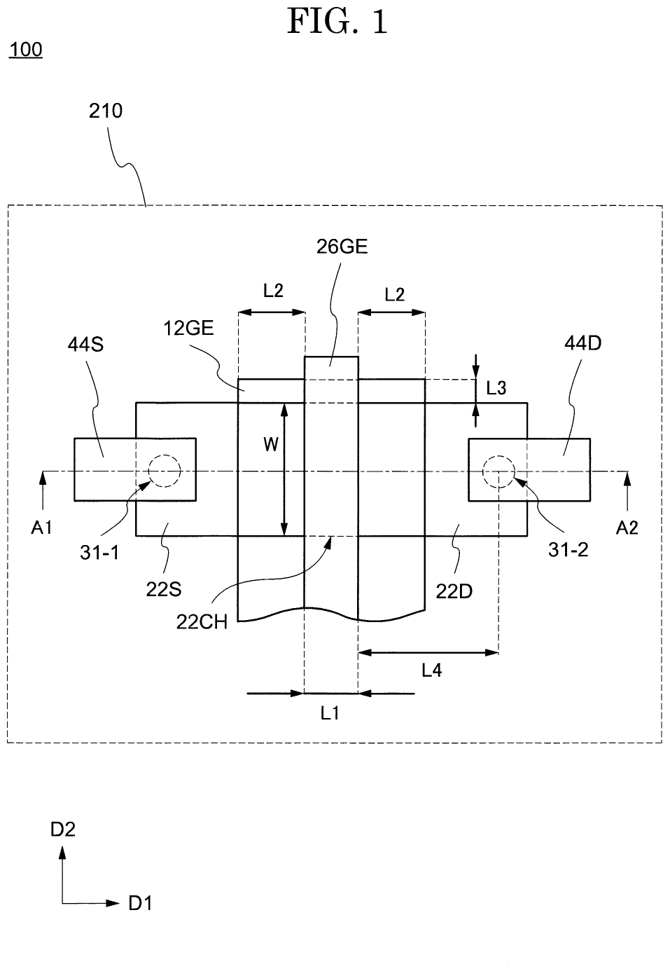

A semiconductor device 100 according to an embodiment of the present invention will be described with reference to FIG. 1 to FIG. 11.

### [Configuration of Semiconductor Device 100]

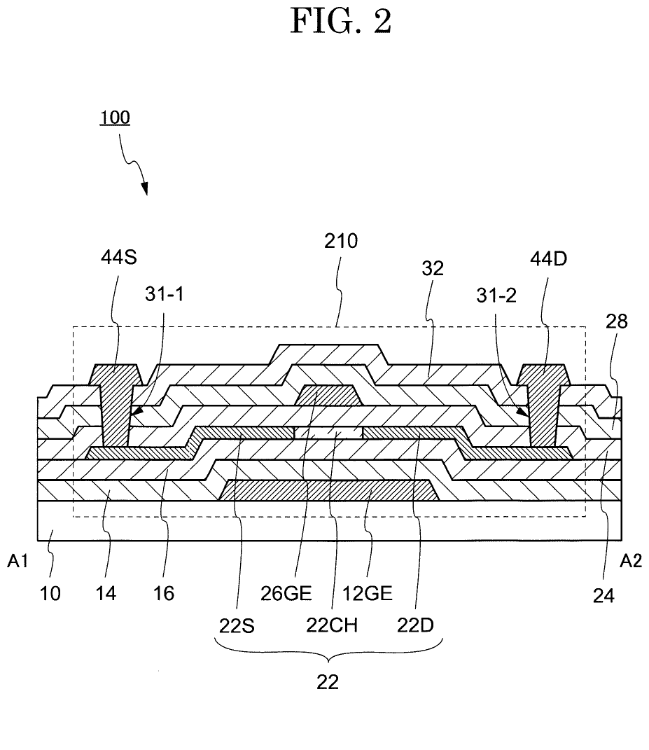

FIG. 1 is a plan view showing an overview of the semiconductor device 100 according to an embodiment of the present invention. FIG. 2 is a cross-sectional view showing an overview of the semiconductor device 100 according to an embodiment of the present invention.

As shown in FIG. 1 and FIG. 2, the semiconductor device 100 includes a transistor 210 provided on a substrate 10. The transistor 210 includes a first gate electrode 12GE, first insulating films 14 and 16, an oxide semiconductor layer 22, a second insulating film 24, and a second gate electrode 26GE. The oxide semiconductor layer 22 include a channel region 22CH, a source region 22S, and a drain region 22D.

The first insulating films 14 and 16 function as a first gate insulating film of the transistor 210. In addition, the second insulating film 24 functions as a second gate insulating film of the transistor 210. Further, third insulating films 28 and 32 function as interlayer insulating films of the transistor 210.

The transistor 210 further includes a source electrode 44S and a drain electrode 44D. The source electrode 44S and the drain electrode 44D are provided on the third insulating film 32. The source electrode 44S and the drain electrode 44D are connected to the oxide semiconductor layer 22 via contact holes 31-1 and 31-2 provided in the second insulating film 24 and the third insulating films 28 and 32.

The oxide semiconductor layer 22 has a polycrystalline structure containing a plurality of crystal grains. Although details will be described later, by using a Poly-OS (Poly-crystalline Oxide Semiconductor) technique, the oxide semiconductor layer 22 having a polycrystalline structure can be formed. Although the configuration of the oxide semiconductor layer 22 will be described below, the oxide semiconductor having a polycrystalline structure may be referred to as a Poly-OS.

The oxide semiconductor layer 22 include two or more metal elements including indium, and the proportion of indium in the two or more metal elements is 50% or more. Gallium (Ga), zinc (Zn), aluminum (Al), hafnium (Hf), yttrium (Y), zirconium (Zr), and lanthanoid-based elements are used as metal elements other than indium. However, it is sufficient that the oxide semiconductor layer 22 contains the Poly-OS, and may include metal elements other than those described above.

A particle diameter of the crystal grain contained in the Poly-OS observed from the top surface of the oxide semiconductor layer 22 (or a thickness direction of the oxide semiconductor layer 22) or a cross section of the oxide semiconductor layer 22 is 0.1 μm or more, preferably 0.3 μm or more, and more preferably 0.5 μm or more. For example, the particle diameter of the crystal grain can be obtained using a cross-sectional SEM observation, a cross-sectional TEM observation, or an Electron Back Scattered Diffraction (EBSD) method.

The thickness of the oxide semiconductor layer 22 is greater than 10 nm and 50 nm or less, preferably greater than 10 nm and 30 nm or less. As described above, since the particle diameter of the crystal grain contained in the Poly-OS is 0.1 μm or more, the oxide semiconductor layer 22 includes a region including only one crystal grain in the thickness direction.

In the Poly-OS, the plurality of crystal grains may have one type of crystal structure, or may have a plurality of types of crystal structures. The crystal structure of the Poly-OS can be identified using an electron diffraction method, an XRD method, or the like. That is, the crystal structure of the oxide semiconductor layer 22 can be identified using the electron diffraction method, the XRD method, or the like.

The crystal structure of the oxide semiconductor layer 22 is preferably cubic. The cubic crystal has a highly symmetric crystal structure, and even if oxygen defects are generated in the oxide semiconductor layer 22, structural relaxation is unlikely to occur, and the crystal structure is stable. As described above, by increasing the proportion of indium, the crystal structure of each of the plurality of crystal grains is controlled, and the oxide semiconductor layer 22 having a cubic crystal structure can be formed.

The oxide semiconductor layer 22 includes a first crystal region that overlaps the second gate electrode 26GE and has a first crystal structure and a second crystal region that does not overlap the second gate electrode 26GE and has a second crystal structure. In this case, the first crystal region corresponds to the channel region 22CH. In addition, the second crystal region corresponds to the source region 22S and the drain region 22D. An electrical conductivity of the second crystal region is greater than an electrical conductivity of the first crystal region.

Further, the second crystal structure is identical to the first crystal structure. In this case, the two crystal structures are identical means that the crystal systems are the same. For example, when the crystal structure of the oxide semiconductor layer 22 is cubic, the first crystal structure of the first crystal region and the second crystal structure of the second crystal region are both cubic and identical. For example, the first crystal structure and the second crystal structure can be identified by a microelectron diffraction method.

Further, in a predetermined crystal orientation, the interplanar spacing d value of the first crystal structure and the interplanar spacing d value of the second crystal structure are substantially the same. In this case, two interplanar spacing d values are substantially the same means that one interplanar spacing d value is 0.95 times or more and 1.05 times or less the other interplanar spacing d value. Alternatively, it refers to the case where two diffraction patterns are almost identical in the microelectron diffraction method.

There may be no grain boundaries between the first crystal region and the second crystal region. In addition, the first crystal region and the second crystal region may be included in one crystal grain. In other words, the change from the first crystal region to the second crystal region may be a continuous crystal structure change.

In addition, the source region 22S and the drain region 22D contain the same impurity elements. Further, since the impurity element is added to the source region 22S and the drain region 22D, their resistivity is lowered compared with the channel region 22CH. In other words, the source region 22S and the drain region 22D have physical properties as conductors.

The concentration of the impurity element contained in the source region 22S and the drain region 22D is preferably 1×10¹⁸ cm⁻³ or more and 1×10²¹ cm⁻³ or less when measured by SIMS analysis (Secondary Ion Mass Spectrometry). In this case, the impurity element means argon (Ar), phosphorus (P), or boron (B).

The impurity element is added to the source region 22S and the drain region 22D, whereby oxygen defects are formed. Hydrogen is trapped in the oxygen defects, so that the resistance of the source region 22S and the drain region 22D can be reduced below the resistance of the channel region 22CH. Further, even if the impurity element is added to the source region 22S and the drain region 22D and oxygen defects are formed, the crystal structure is maintained without breaking. Therefore, it can be said that the crystal structure of the source region 22S and the drain region 22D is the same as the crystal structure of the channel region 22CH.

When many oxygen defects are contained in the layer in the channel region of the oxide semiconductor layer, hydrogen is trapped in the oxygen defects, which adversely affects the properties of the transistor. Therefore, it is desired to reduce oxygen defects contained in the oxide semiconductor layer.

For the oxide semiconductor, oxygen defects are less likely to form in a crystalline oxide semiconductor than in an amorphous oxide semiconductor. Further, it is known that the crystalline oxide semiconductor is easily obtained by relatively increasing the proportion of indium contained in the oxide semiconductor. However, even if the crystalline oxide semiconductor is obtained with a relatively high proportion of indium, there are more oxygen defects than necessary. The oxygen defects can be repaired by being supplied with oxygen. Therefore, the oxygen defects in the oxide semiconductor layer needs to be repaired by arranging an insulating film capable of releasing oxygen as the insulating film around the oxide semiconductor layer.

On the other hand, if more oxygen than necessary is supplied to the oxide semiconductor layer, a defect level different from the oxygen defects is formed due to the excessive oxygen contained in the oxide semiconductor layer. As a result, phenomena such as characteristic fluctuation due to the reliability test, a decrease in field-effect mobility, or characteristic variation may occur.

In the present embodiment, the oxide semiconductor layer 22 contains the Poly-OS. The oxide semiconductor layer 22 containing the Poly-OS is a layer having high crystallinity and sufficiently reduced oxygen defects.

Further, in the present embodiment, the source region 22S and the drain region 22D are formed in the oxide semiconductor layer 22 of the transistor 210 by performing ion-implantation using the second gate electrode 26GE as a mask. Depending on a channel length of the transistor and a width of the first gate electrode 12GE, the reliability test tends to deteriorate the properties of the transistor by applying a strong electric field not only to the channel region of the transistor but also to the junction between the channel region and the source region and the junction between the channel region and the drain region. For example, the threshold voltage of the transistor may shift in the negative direction.

In this case, for example, the reliability test refers to an NBTIS (Negative Bias Temperature Illumination Stress) test. In addition, a BT stress test such as the NBTIS is a kind of accelerated test, and a characteristic change (aging) of a transistor caused by long-term use can be evaluated in a short time. In particular, the variation in the threshold voltage of the transistor before and after the BT stress test is a critical indicator for examining the reliability. It can be said that the transistor has higher reliability as the variation in the threshold voltage decreases before and after the BT stress test.

An object of an embodiment of the present invention is to suppress the threshold variation of a transistor in a semiconductor device and improve reliability.

When the transistor 210 is in a plan view, the first gate electrode 12GE that functions as the back gate has a first region that overlaps the oxide semiconductor layer 22 and protrudes from the second gate electrode 26GE that functions as a top gate to a first direction D1, and a second region that overlaps the second gate electrode 26GE and protrudes from the oxide semiconductor layer 22 to a second direction D2 that intersects the first direction D1.

As a result, the channel region 22CH in the oxide semiconductor layer 22, the junction between the channel region 22CH and the source region 22S, and the junction between the channel region 22CH and the drain region 22D are covered with the first gate electrode 12GE. As a result, in the NBTIS test, it is possible to suppress the junction between the channel region 22CH and the source region 22S of the transistor 210 and the junction between the channel region 22CH and the drain region 22D from being deteriorated by the electric field applied to the first gate electrode 12GE. Therefore, it is possible to suppress the threshold value of the transistor 210 from shifting in the negative direction. As a result, the threshold variation of the transistor 210 is suppressed, and the semiconductor device 100 with improved reliability can be obtained.

In this case, a width of the second gate electrode 26GE (a length in the first direction D1) is referred to as a channel length L1. In addition, a length by which the first gate electrode 12GE protrudes from the end portion of the second gate electrode 26GE in the first direction D1 is referred to as a length L2. A length by which the first gate electrode 12GE protrudes from the oxide semiconductor layer 22 in the second direction D2 is referred to as a length L3. A length from the end portion of the second gate electrode 26GE to the source electrode 44S (or the center of the contact hole) is referred to as a length L4. Further, as shown in FIG. 1, in the oxide semiconductor layer 22, the length L4 (also referred to as a first length) from the end portion of the second gate electrode 26GE to the source electrode 44S in the first direction D1 may be equal to or greater than the length L2 (also referred to as a second length). That is, the first region overlaps at least a part of the second crystal region. In the transistor 210, the entire the oxide semiconductor layer 22 may not be covered with the first gate electrode 12GE. As a result, a region where the first gate electrode 12GE formed of a metal material or the like is arranged can be reduced. In the case where the transistor 210 is applied to a display device or the like, a region shielded by the transistor 210 can be reduced. That is, the aperture ratio of the pixel included in the display device can be improved.

In addition, as shown in FIG. 1, the first direction D1 is the same direction as the channel length L1 of the transistor, and the second direction D2 is the channel width direction of the transistor. The length L2 may be equal to or greater than the channel length L1. In addition, the length L3 (also referred to as a third length) may be smaller than the channel length L1. For example, in the case where the channel length L1 is 3 μm, the length L2 may be 3 μm or more, and the length L3 may be 2 μm. By arranging the first gate electrode 12GE in this manner, it is possible to reduce the area occupied by the transistor (in particular, to reduce a light-shielding region of the transistor) and to reduce the design-load, while suppressing the variation in the threshold voltage of the transistor.

Further, in the oxide semiconductor layer 22, since the source region 22S and the drain region 22D have the crystal structure as well as the channel region 22CH, the resistance of the source region 22S and the drain region 22D can be sufficiently reduced. Therefore, the parasitic resistance of the source region 22S and the drain region 22D is reduced, and the variation in the on-state current in the electrical characteristics of the transistor 210 can be suppressed. Since the transistor 210 has a large mobility, when the semiconductor device 100 is used for a display device or the like, the variation is suppressed and the performance is improved.

In the semiconductor device 100 according to an embodiment of the present invention, electrical characteristics having a mobility of 30 cm²/Vs or more, 35 cm²/Vs or more, or 40 cm²/Vs or more can be obtained in a range where the channel length L1 of the channel region CH of the transistor 210 is 2 μm or more and 4 μm or less and the channel width W of the channel region CH is 2 μm or more and 25 μm or less. The mobility in the present specification and the like refers to a field-effect mobility in a saturated region of the transistor, and means the maximum value of the field-effect mobility in a region where a potential difference (Vd) between the source electrode and the drain electrode is greater than a value (Vg−Vth) obtained by subtracting a threshold voltage (Vth) of the transistor from a voltage (Vg) supplied to the gate electrode.

In the present embodiment, although a configuration in which a dual-gate transistor for driving the transistor by the first gate electrode 12GE and the second gate electrode 26GE is used as the transistor 210 is exemplified, the present invention is not limited to this configuration. A top-gate transistor that drives the transistor by the second gate electrode 26GE may be used as the transistor 210. For example, a bottom-gate transistor that drives the transistor by the first gate electrode 12GE may be used as the transistor 210. The above configuration is merely an embodiment, and the present invention is not limited to the above configuration.

The first gate electrode 12GE has a function as the bottom gate of the transistor 210 and a light-shielding film for the oxide semiconductor layer 22. The first insulating films 14 and 16 and the second insulating film 24 have a function of releasing oxygen by heat treatment in the manufacturing process. The second insulating film 24 and the third insulating films 28 and 32 have a function of insulating the first gate electrode 12GE from the source electrode 44S and the drain electrode 44D and reducing parasitic capacitance therebetween. The operation of the transistor 210 is controlled mainly by a voltage supplied to the second gate electrode 26GE. An auxiliary voltage is supplied to the first gate electrode 12GE. In addition, the first gate electrode 12GE may be simply used as a light-shielding film, where no specific voltage is supplied to the first gate electrode 12GE, and may be floating.

### [Method for Manufacturing Semiconductor Device 100]

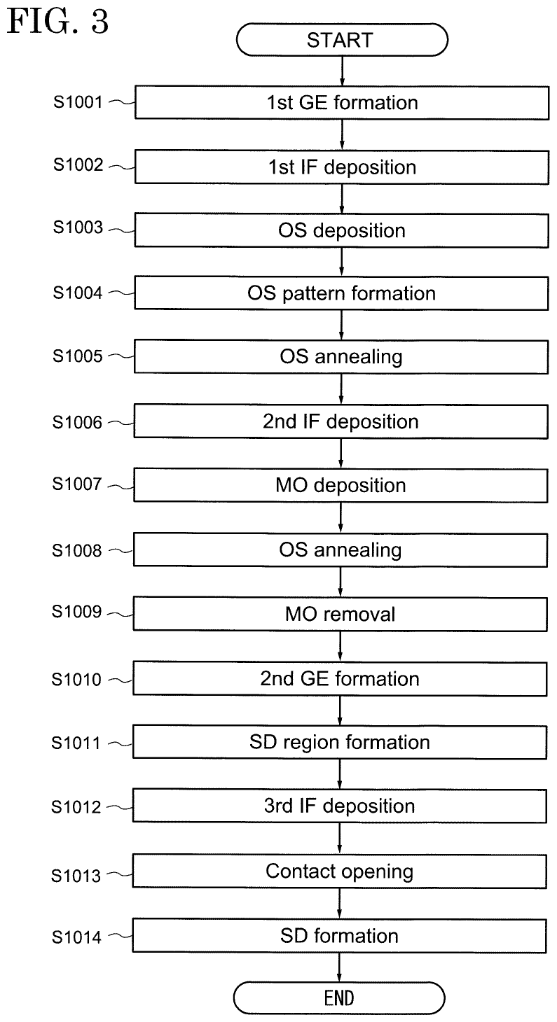

A method for manufacturing the semiconductor device 100 according to an embodiment of the present invention will be described with reference to FIG. 3 to FIG. 10. FIG. 3 is a sequence diagram showing a method for manufacturing the semiconductor device 100 according to an embodiment of the present invention.

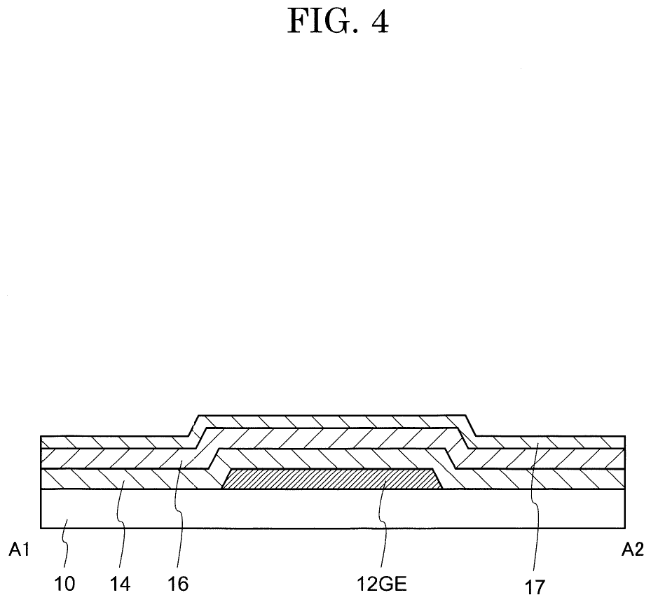

As shown in FIG. 3 and FIG. 4, the first gate electrode 12GE is formed on the substrate 10 (“1st GE formation” in step S1001 shown in FIG. 3).

A rigid substrate having light transmittance, such as a glass substrate, a quartz substrate, or a sapphire substrate, is used as the substrate 10. In the case where the substrate 10 needs to have flexibility, a substrate containing a resin, such as a polyimide substrate, an acryl substrate, a siloxane substrate, or a fluororesin substrate, is used as the substrate 10. In the case where a substrate containing a resin is used as the substrate 10, an impurity element may be introduced into the resin in order to improve the heat resistance of the substrate 10. In particular, in the case where the semiconductor device 100 is a top-emission display, the substrate 10 does not need to be transparent, so that an impurity that reduces the transparency of the substrate 10 may be used. In the case where the semiconductor device 100 is used for an integrated circuit other than a display device, a substrate that does not have light transmittance, such as a silicon substrate, a silicon carbide substrate, a semiconductor substrate, such as a compound semiconductor substrate, or a conductive substrate, such as stainless steel, may be used as the substrate 10.

The first gate electrode 12GE is formed by processing a conductive film formed by a sputtering method. A common metal material is used as the first gate electrode 12GE. For example, aluminum (Al), titanium (Ti), chromium (Cr), cobalt (Co), nickel (Ni), molybdenum (Mo), hafnium (Hf), tantalum (Ta), tungsten (W), bismuth (Bi), silver (Ag), copper (Cu), and an alloy or compound thereof are used as the first gate electrode 12GE. The above-described materials may be used in a single layer or a stacked layer as the first gate electrode 12GE.

As shown in FIG. 3 and FIG. 4, the first insulating films 14 and 16 are formed on the substrate 10 and the first gate electrode 12GE (“1st IF deposition” in step S1002 shown in FIG. 3). The first insulating films 14 and 16 are deposited by a CVD (Chemical Vapor Deposition) method or a sputtering method. Common insulating materials are used as the first insulating films 14 and 16. For example, an inorganic insulating material such as silicon oxide (SiOₓ), silicon oxynitride (SiOₓN_{y}), silicon nitride (SiNₓ), or silicon nitride oxide (SiNₓO_{y}) is used as the first insulating films 14 and 16. The above SiOₓN_{y} is a silicon compound containing a smaller proportion (x>y) of nitrogen (N) than oxygen (O). SiNₓO_{y} is a silicon compound containing a smaller proportion of oxygen than nitrogen (x>y). In the present embodiment, the first insulating films 14 and 16 are formed by stacking a silicon nitride film and a silicon oxide film on the silicon nitride film. For example, the combined thickness of the first insulating films 14 and 16 is 100 nm or more and 600 nm or less, preferably 150 nm or more and 300 nm or less.

The first insulating films 14 and 16 are preferably formed from the substrate 10 in the order of an insulating material containing nitrogen and an insulating material containing oxygen. For example, by using an insulating material containing nitrogen as the first insulating film 14, impurities diffusing from the substrate 10 toward the oxide semiconductor layer 22 can be blocked. In addition, by using an insulating material containing oxygen as the first insulating film 16, oxygen can be released by heat treatment. For example, the temperature of the heat treatment at which the insulating material containing oxygen releases oxygen is 500° C. or lower, 450° C. or lower, or 400° C. or lower. That is, for example, the insulating material containing oxygen releases oxygen at the heat treatment temperature performed in the method for manufacturing the semiconductor device 100 when a glass substrate is used as the substrate 10. In the present embodiment, although an example in which a stacked structure of silicon nitride and silicon oxide is used as the first insulating films 14 and 16 is described, a single-layer structure of the above material may be used as the first insulating film.

As shown in FIG. 3 and FIG. 4, an oxide semiconductor film 17 is deposited on the first insulating film 16 (“1st OS deposition” in step S1003 shown in FIG. 3). This process may be expressed as “the oxide semiconductor film 17 is formed on the substrate 10”. The oxide semiconductor film 17 is deposited by a sputtering method or an atomic layer deposition method (ALD). For example, a thickness of the oxide semiconductor film 17 is greater than 10 nm and 30 nm or less.

A metal oxide having semiconductor properties can be used as the oxide semiconductor film 17. An oxide semiconductor containing two or more metal elements including indium is used as the oxide semiconductor film 17. In addition, the proportion of indium in the two or more metal elements is 50% or more. Gallium (Ga), zinc (Zn), aluminum (Al), hafnium (Hf), yttrium (Y), zirconium (Zr), or a lanthanoid-based element is used as metal elements other than indium.

In the case of crystallizing the oxide semiconductor film 17 by the OS annealing described below, the oxide semiconductor film 17 after film formation and prior to OS annealing is preferably amorphous (crystalline components of oxide semiconductor is small). In other words, the deposition method of the oxide semiconductor film 17 is preferably a condition that the oxide semiconductor film 17 immediately after the deposition does not crystallize as much as possible. For example, in the case where the oxide semiconductor film 17 is deposited by a sputtering method, the oxide semiconductor film 17 is deposited while controlling a temperature of the deposition target (the substrate 10 and the structure formed thereon).

When the deposition is performed on the deposition target by the sputtering method, ions generated in the plasma and atoms recoiled by the sputtering target collide with the deposition target, so that the temperature of the deposition target increases with the deposition process. When the temperature of the deposition target during the deposition process increases, microcrystals are contained in the oxide semiconductor film 17 immediately after the deposition process. If the oxide semiconductor film 17 contains microcrystals, the particle diameter cannot be increased by the subsequent OS annealing. In order to control the temperature of the deposition target as described above, for example, the deposition can be performed while cooling the deposition target. For example, the deposition target can be cooled from the surface opposite to the deposition surface so that the temperature of the deposition surface of the deposition target (hereinafter, referred to as “deposition temperature”) is 100° C. or lower, 70° C. or lower, 50° C. or lower, or 30° C. or lower. In particular, the deposition temperature of the oxide semiconductor film 17 of the present embodiment is preferably 50° C. or lower. By forming the oxide semiconductor film 17 while cooling the substrate, it is possible to obtain the oxide semiconductor film 17 with few crystalline components immediately after the deposition. In the present embodiment, the oxide semiconductor film 17 is formed at a deposition temperature of 50° C. or lower, and the OS annealing described later is performed at a heating temperature of 400° C. or higher. As described above, in the present embodiment, the difference between the temperature at which the oxide semiconductor film 17 is formed and the temperature at which the OS annealing is performed on the oxide semiconductor film 17 is preferably 350° C. or higher.

In the sputtering process, an amorphous oxide semiconductor film 17 is formed under the condition of an oxygen partial pressure of 10% or less. When the oxygen partial pressure is high, the oxide semiconductor film 17 immediately after the deposition contains microcrystals due to excessive oxygen contained in the oxide semiconductor film 17. Therefore, the deposition of the oxide semiconductor film 17 is preferably performed under the condition of low oxygen partial pressure. For example, the oxygen partial pressure is 3% or more and 5% or less, preferably 3% or more and 4% or less. Further, in the case where the oxide semiconductor film 17 is deposited under the condition of an oxygen partial pressure of 2%, the oxide semiconductor film may not crystallize even if the OS annealing is performed later.

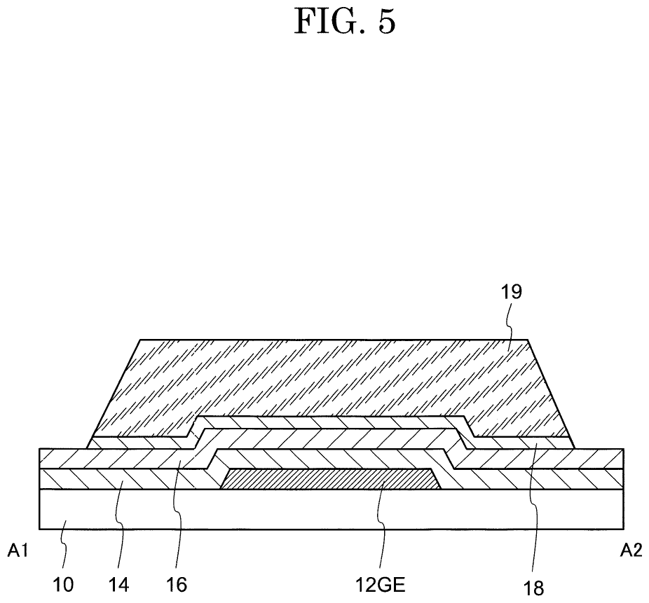

As shown in FIG. 3 and FIG. 5, a pattern of an oxide semiconductor layer 18 is formed (“OS pattern formation” in step S1004 shown in FIG. 3). A resist mask 19 is formed on the oxide semiconductor film 17, and the oxide semiconductor film 17 is etched using the resist mask 19. Wet etching may be used, or dry etching may be used as the etching of the oxide semiconductor film 17. The etching can be performed using an acidic etchant. For example, oxalic acid, PAN, sulfuric acid, hydrogen peroxide solution, or hydrofluoric acid can be used as the etchant. As a result, a patterned oxide semiconductor layer 18 can be formed. After that, the resist mask 19 is removed.

The pattern of the oxide semiconductor film 17 is preferably formed before the OS annealing. The etching of the oxide semiconductor film 17 tends to be difficult when the oxide semiconductor film 17 is crystallized by the OS annealing. In addition, even if the patterned oxide semiconductor layer 18 is damaged by the etching, the damage of the oxide semiconductor layer 18 can be repaired by the OS annealing, which is preferable.

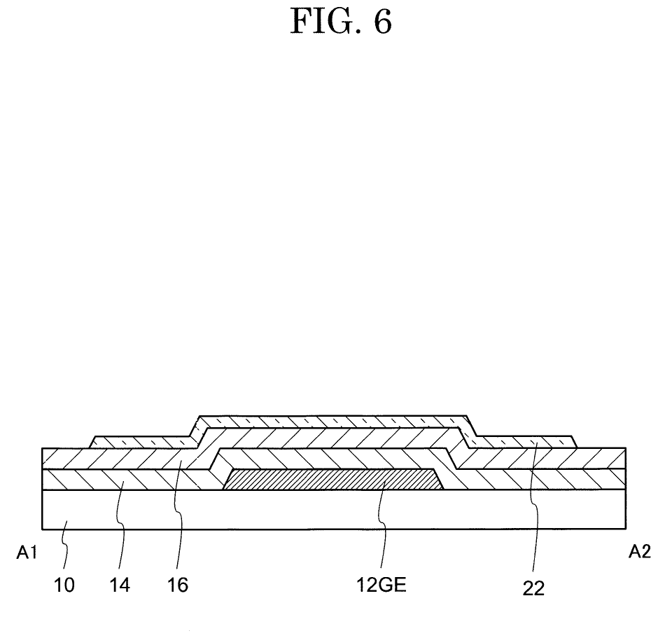

As shown in FIG. 3 and FIG. 6, the pattern of the oxide semiconductor layer 18 is formed, and then the heat treatment (OS annealing) is performed on the oxide semiconductor layer 18 (“OS annealing” in step S1005 shown in FIG. 3). In the OS annealing, the oxide semiconductor layer 18 is held at a predetermined reaching temperature for a predetermined time. The predetermined reaching temperature is 300° C. or higher and 500° C. or lower, preferably 350° C. or higher and 450° C. or lower. In addition, the holding time at the reaching temperature is 15 minutes or more and 120 minutes or less, preferably 30 minutes or more and 60 minutes or less. By performing the OS annealing, the oxide semiconductor layer 18 is crystallized, and the oxide semiconductor layer 22 having a polycrystalline structure is formed.

In a thin film transistor, by reducing the thickness of the oxide semiconductor layer, carriers in the vicinity of the interface with the gate insulating film tend to be increased, and the field-effect mobility tends to be increased. In other words, the thin film transistor tends to have higher field-effect mobility as the thickness of a region that functions as a channel of the oxide semiconductor layer smaller. Therefore, the smaller the thickness of the oxide semiconductor layer, the better. However, even if the oxide semiconductor layer is deposited with a thickness of 10 nm or less and then the heat treatment is performed, the oxide semiconductor layer may not be sufficiently crystallized.

Further, in the thin film transistor, the crystallinity of the oxide semiconductor layer 22 contributes to the improvement of the field-effect mobility. Therefore, the oxide semiconductor layer 22 preferably has a polycrystalline structure. However, when microcrystals are contained in the oxide semiconductor film 17 at the time of deposition, the particle diameter of the crystal grain having a polycrystalline structure cannot be increased even if the heat treatment is performed thereafter. As described above, it is difficult to achieve both thinning of the oxide semiconductor layer and good crystallization.

Therefore, when the oxide semiconductor film 17 is deposited by a sputtering method, the film is deposited at a low oxygen partial pressure of 3% or more and 5% or less. By forming the oxide semiconductor film 17 under the condition where the oxygen partial pressure is low, it is possible to suppress excessive oxygen from being contained in the oxide semiconductor film 17, and it is possible to suppress microcrystals from being contained in the oxide semiconductor film 17 immediately after the deposition. As a result, it is possible to suppress the growth of crystals from the microcrystals during the heat treatment of the oxide semiconductor layer 18. Therefore, even if the oxide semiconductor film 17 is deposited to have a thickness greater than 10 nm and 30 nm or less, the particle diameter of the crystal grain having a polycrystalline structure of the oxide semiconductor layer 22 can be increased.

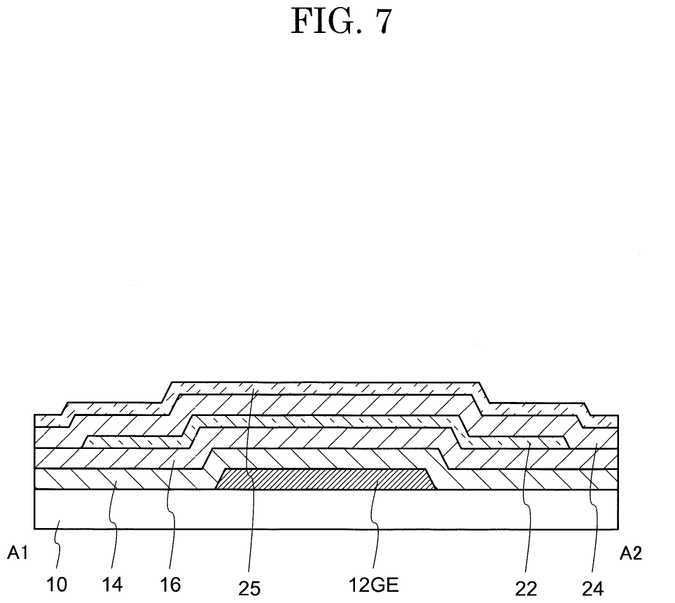

As shown in FIG. 3 and FIG. 7, the second insulating film 24 is formed on the oxide semiconductor layer 22 (“2nd IF deposition” in step S1006 shown in FIG. 3). The deposition method and insulating material of the second insulating film 24 may be referred to the explanation of the first insulating films 14 and 16. For example, the thickness of the second insulating film 24 is 50 nm or more and 300 nm or less, 60 nm or more and 200 nm or less, or 70 nm or more and 150 nm or less.

An insulating material containing oxygen is preferably used as the second insulating film 24. An insulating film with few defects is preferably used as the second insulating film 24. For example, when the composition ratio of oxygen in the second insulating film 24 and the composition ratio of oxygen in the insulating film having a composition similar to that of the second insulating film 24 (hereinafter referred to as “another insulating film”) are compared, the composition ratio of oxygen in the second insulating film 24 is closer to the stoichiometric ratio with respect to the insulating film than the composition ratio of oxygen in the other insulating film. For example, in the case where silicon oxide (SiOₓ) is used for each of the second insulating film 24 and the third insulating film 32, the composition ratio of oxygen in the silicon oxide used as the second insulating film 24 is close to the stoichiometric ratio of silicon oxide compared with the composition ratio of oxygen in the silicon oxide used as the third insulating film 32. For example, a film in which no defects are observed when evaluated by an electron-spin resonance (ESR) method may be used as the second insulating film 24.

In order to form the insulating film with few defects as the second insulating film 24, the second insulating film 24 may be deposited at a deposition temperature of 350° C. or higher. The second insulating film 24 is deposited, and then an oxygen-implanting process may be performed on a part of the second insulating film 24. In the present embodiment, silicon oxide is formed as the second insulating film 24 at a deposition temperature of 350° C. or higher in order to form the insulating film with few defects.

As shown in FIG. 3 and FIG. 7, a metal oxide film 25 is formed on the second insulating film 24 (“MO deposition” in step S1007 shown in FIG. 3). The metal oxide film 25 is deposited by sputtering. Since the metal oxide film 25 is deposited by the sputtering method, oxygen is implanted into the second insulating film 24.

A metal oxide containing aluminum as a main component is used as the metal oxide film 25. For example, an inorganic insulating layer such as aluminum oxide (AlOₓ), aluminum oxynitride (AlOₓN_{y}), aluminum nitride oxide (AlNₓO_{y}), or aluminum nitride (AlNₓ) is used as the metal oxide film 25. The metal oxide film containing aluminum as a main component means that the proportion of aluminum contained in the metal oxide film is 1% or more of the entire metal oxide film 25. The proportion of aluminum contained in the metal oxide film 25 may be 5% or more and 70% or less, 10% or more and 60% or less, or 30% or more and 50% or less of the entire metal oxide film 25. The ratio may be a mass ratio or a weight ratio.

For example, the thickness of the metal oxide film 25 is 5 nm or more and 100 nm or less, 5 nm or more and 50 nm or less, 5 nm or more and 30 nm or less, or 7 nm or more and 15 nm or less. In the present embodiment, aluminum oxide is used as the metal oxide film 25. Aluminum oxide has a high barrier property against gases such as oxygen or hydrogen. In the present embodiment, the aluminum oxide used as the metal oxide film 25 suppresses the diffusion of oxygen implanted into the second insulating film 24 outward at the time of the deposition of the metal oxide film 25. In other words, the barrier property refers to a function of suppressing gases such as oxygen and hydrogen from permeating the aluminum oxide. That is, even if a gas such as oxygen is present in the layer provided under the aluminum oxide film, the gas does not move to the layer provided above the aluminum oxide film. Alternatively, even if a gas such as oxygen is present in the layer provided on the aluminum oxide film, the gas does not move to the layer provided below the aluminum oxide film.

For example, in the case where the metal oxide film 25 is deposited by the sputtering method, a process gas used in sputtering remains in the metal oxide film 25. For example, in the case where Ar is used as the process gas for sputtering, Ar may remain in the second insulating film 24. The residual Ar can be detected by SIMS (Secondary Ion Mass Spectrometry) analysis of the second insulating film 24.

With the second insulating film 24 and the metal oxide film 25 formed on the oxide semiconductor layer 22, heat treatment (oxidation annealing) for supplying oxygen from the second insulating film 24 to the oxide semiconductor layer 22 is performed (“oxidation annealing” in step S1008 shown in FIG. 3). Many oxygen defects are generated on the upper surface and the side surface of the oxide semiconductor layer 22 in a process from the deposition of the oxide semiconductor film 17 to the deposition of the second insulating film 24 on the oxide semiconductor layer 22. Oxygen released from the first insulating film 16 and the second insulating film 24 is supplied to the oxide semiconductor layer 22 by the oxidation annealing, and the oxygen defects are repaired.

In the oxidation annealing, the oxygen implanted into the second insulating film 24 is blocked by the metal oxide film 25, and is therefore suppressed from being released into the atmosphere. Therefore, the oxygen is efficiently supplied to the oxide semiconductor layer 22 by the oxidation annealing, and the oxygen defects are repaired.

As shown in FIG. 3, the metal oxide film 25 is etched (removed) (“MO removal” in step S1009 shown in FIG. 3). Wet etching may be used, or dry etching may be used as the etching of the metal oxide film 25. For example, dilute hydrofluoric acid (DHF) is used as the wet etching.

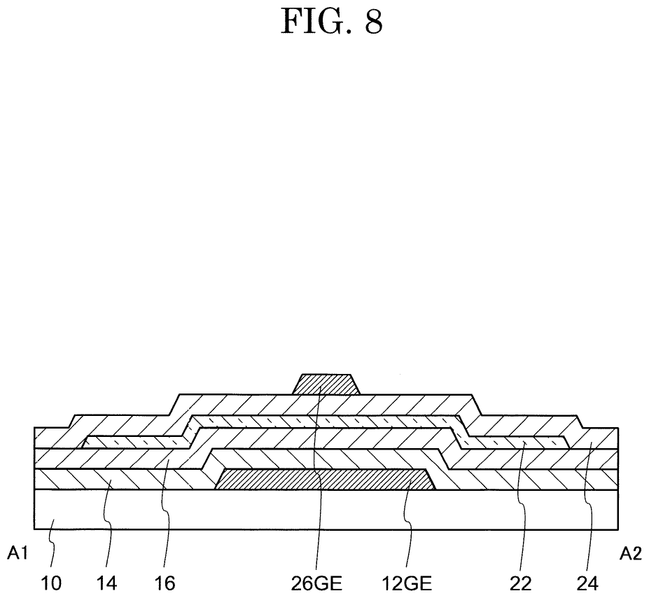

As shown in FIG. 3 and FIG. 8, the second gate electrode 26GE is formed on the second insulating film 24 (“2nd GE formation” in S1010 shown in FIG. 3). The second gate electrode 26GE is formed by processing the conductive film formed by a sputtering method. Materials that can be used as the second gate electrode 26GE may be referred to the description of the material of the first gate electrode 12GE. The materials described in the explanation of the first gate electrode 12GE may be used in a single layer or a stacked layer as the second gate electrode 26GE. In addition, the material of the second gate electrode 26GE may be the same material as the first gate electrode 12GE.

The width of the second gate electrode 26GE (the length in the first direction D1 in FIG. 2) corresponds to the channel length L1. In a plan view, the first gate electrode 12GE includes the first region protruding from the second electrode 26GE to the first direction D1 and the second region protruding from the oxide semiconductor layer 22 in the second direction D2 intersecting the first direction D1. Further, the length L2 in the first direction D1 in the first region is preferably longer than the length L3 in the second D2 in the second region.

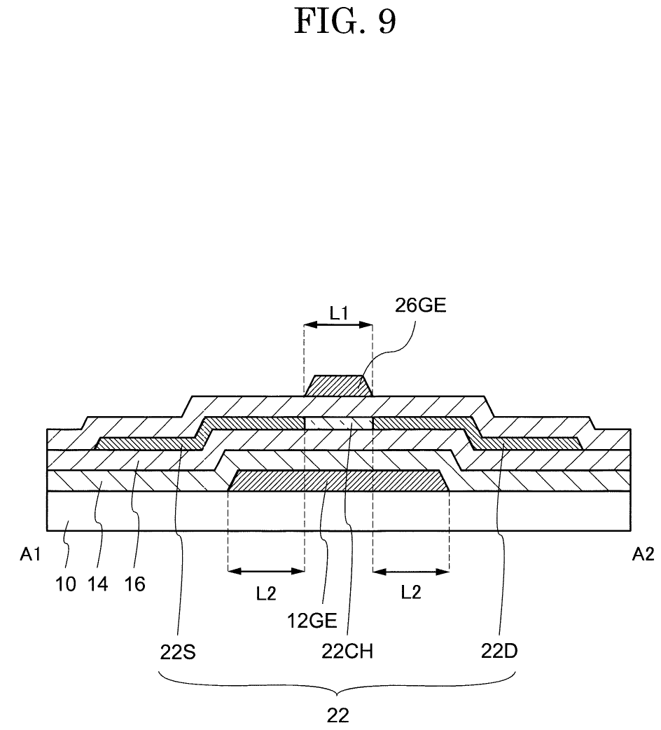

As shown in FIG. 3 and FIG. 9, an impurity element is added to the oxide semiconductor layer 22 using the second gate electrode 26GE as a mask (“SD region formation” in step S1011 shown in FIG. 3). Although the case where an impurity element is added by ion implantation is described in the present embodiment, the impurity element may be added by an ion doping method.

Specifically, an impurity element is added to the source region 22S and the drain region 22D through the second insulating film 24 by ion-implantation. In the oxide semiconductor layer 22, no impurity element is added to the region overlapping the second gate electrode 26GE, and functions as the channel region 22CH. For example, argon (Ar), phosphorus (P), or boron (B) may be used as the impurity element. Further, in the case where boron (B) is added by the ion-implantation method, the acceleration energy may be set to 20 keV or more and 40 keV or less, and the implantation amount of boron (B) may be set to 1×10¹⁴ cm⁻² or more and 1×10¹⁶ cm⁻² or less.

Impurity elements can be added to the source region 22S and the drain region 22D at a concentration of 1×10¹⁸ cm⁻³ or more and 1×10²¹ cm⁻³ or less. In this case, an impurity element is added to the oxide semiconductor in the source region 22S and the drain region 22D, and then oxygen defects are formed. Hydrogen is easily trapped in the oxygen defects. As a result, resistance ratio of the source region 22S and the drain region 22D can be reduced to function as conductors. Even if an impurity element is added to the oxide semiconductor layer 22 and oxygen defects are formed, the crystal structure is maintained without breaking. Therefore, it can be said that the crystal structure of the source region 22S and the drain region 22D is the same as the crystal structure of the channel region 22CH.

For example, in the case where an IGZO-based oxide semiconductor layer is used, the oxide semiconductor layer has a large resistance, so that the resistance of the source region and the drain region cannot be sufficiently reduced unless the thickness is increased. On the other hand, in the oxide semiconductor layer 22 having a polycrystalline structure, an impurity element is added to the source region 22S and the drain region 22D, so that the resistance of the source region 22S and the drain region 22D can be 10000/sq. or less, preferably 5000/sq. or less, and more preferably 2500/sq. or less.

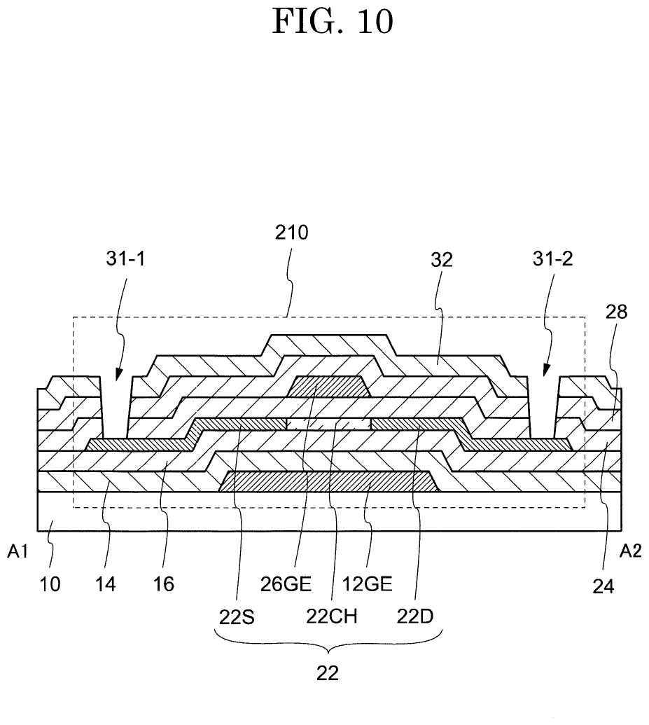

As shown in FIG. 3 and FIG. 10, the third insulating films 28 and 32 are formed on the second insulating film 24 and the second gate electrode 26GE (“3rd IF deposition” in step S1012 shown in FIG. 3). The deposition method and insulating material of the third insulating films 28 and 32 may be referred to the explanation of the material of the first insulating films 14 and 16. In the present embodiment, for example, silicon nitride is formed as the third insulating film 28, and silicon oxide is formed as the third insulating film 32. The third insulating films 28 and 32 function as the interlayer insulating film of the transistor 210.

As shown in FIG. 3 and FIG. 10, the contact holes 31-1 and 31-2 are formed in the second insulating film 24 and the third insulating films 28 and 32 (“Contact opening” in step S1013 shown in FIG. 3). As a result, the source region 22S and the drain region 22D of the oxide semiconductor layer 22 are exposed.

Finally, as shown in FIG. 3, the source electrode 44S and the drain electrode 44D are formed on the third insulating films 28 and 32 (“SD formation” in step S1014 shown in FIG. 3). The source electrode 44S and the drain electrode 44D are formed by processing the conductive film formed by a sputtering method. As a result, the source region 22S and the source electrode 44S are connected, and the drain region 22D and the drain electrode 44D are connected. The material that can be used for the source electrode 44S and the drain electrode 44D may be referred to the description of the material of the first gate electrode 12GE.

Through the above steps, the semiconductor device 100 shown in FIG. 1 and FIG. 2 can be manufactured.

### First Modification

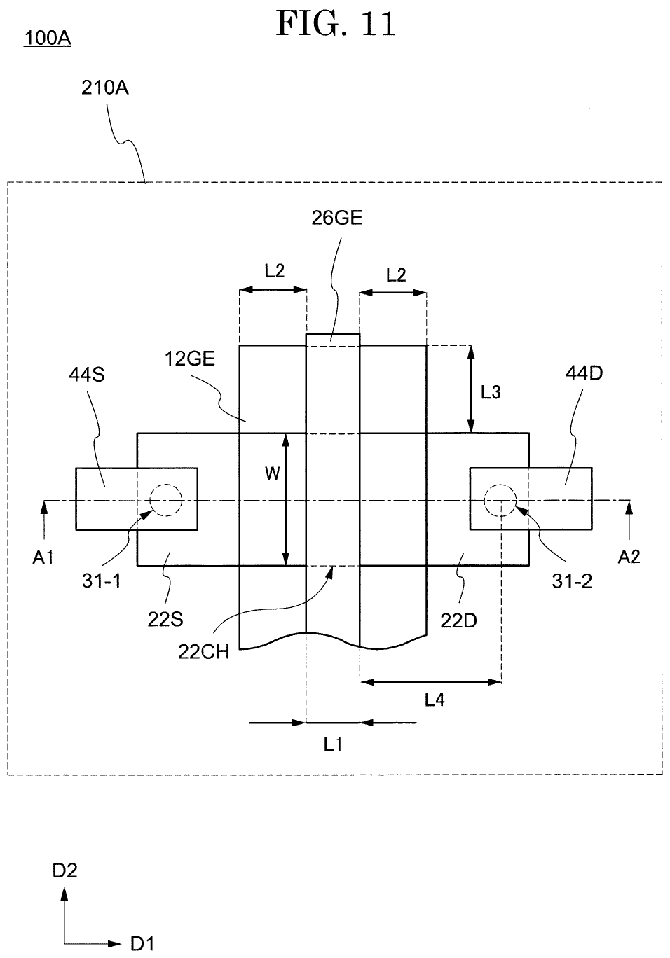

FIG. 11 is a plan view showing a semiconductor device 100A having a structure partially different from that of the semiconductor device 100. As shown in FIG. 11, in a transistor 210A of the semiconductor device 100A, the first gate electrode 12GE is different from the transistor 210. Further, in the transistor 210A, since the cross-sectional view in an A1-A2 line is similar to that in the cross-sectional view shown in FIG. 2, detailed explanations thereof will be omitted.

In a plan view, the transistor 210A is similar to the transistor 210 in that the first gate electrode 12GE has the first region protruding from the second gate electrode 26GE in the first direction D1 and the second region overlapping the second gate electrode 26GE and protruding from the oxide semiconductor layer 22 in the second direction D2. The transistor 210A is different from the transistor 210 in that the length L2 in the first direction D1 in the first region is shorter than the length L3 in the second direction D2 in the second region. In this case, the length L2 is preferably the channel length L1 or more of the transistor, but it is sufficient that the first gate electrode 12GE protrudes from the oxide semiconductor layer 22 in the second direction D2. Even if the length L2 is shorter than the length L3, when the first gate electrode 12GE protrudes from the oxide semiconductor layer 22 in the second direction D2, it is possible to suppress the threshold value of the transistor 210A from shifting in the negative direction. Therefore, the threshold variation of the transistor 210A is suppressed, and the semiconductor device 100 with improved reliability can be obtained.

### Second Embodiment

In the present embodiment, a semiconductor device 100B having a configuration partially different from that of the semiconductor device 100 described in the first embodiment will be described.

### [Configuration of Semiconductor Device 100B]

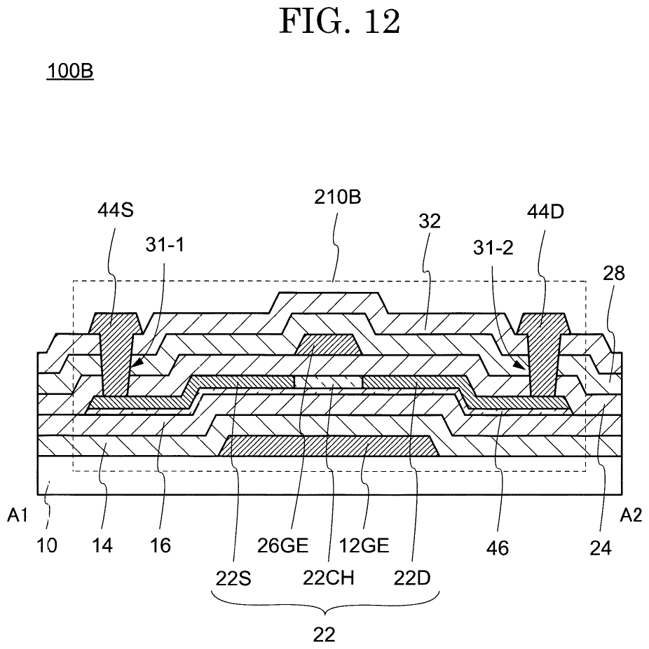

FIG. 12 is a cross-sectional view showing an overview of the semiconductor device 100B according to an embodiment of the present invention.

As shown in FIG. 12, the semiconductor device 100B includes a transistor 210B provided on the substrate 10. In addition, the configuration of the transistor 210B is generally similar to the configuration of the transistor 210, but differs in that a metal oxide layer 46 is provided between the oxide semiconductor layer 22 and the first insulating film 16. In addition, since the plan view when the transistor 210B is in a plan view is similar to that in FIG. 2, the illustration thereof is omitted.

A metal oxide containing aluminum as a main component is used as the metal oxide layer 46. A material similar to that of the metal oxide film 25 can be used as the metal oxide layer 46. For example, the thickness of the metal oxide layers 46 is 1 nm or more and 100 nm or less, 1 nm or more and 50 nm or less, 1 nm or more and 30 nm or less, or 1 nm or more and 10 nm or less. In the present embodiment, aluminum oxide is used as the metal oxide layer 46. Aluminum oxide has a high barrier property against gases. In the present embodiment, the aluminum oxide used as the metal oxide layer 46 blocks hydrogen and oxygen released from the first insulating film 16 and the third insulating film 32, and suppresses the released hydrogen and oxygen from reaching the oxide semiconductor layer 22.

When oxygen is supplied excessively to the oxide semiconductor layer 22, a defect level different from the oxygen defects is formed due to the excessive oxygen. As a result, phenomena such as characteristic fluctuation due to the reliability test, a decrease in field-effect mobility, or characteristic variation may occur.

By providing the metal oxide layer 46 below the oxide semiconductor layer 22, excessive oxygenation can be suppressed from being supplied to the lower surface of the oxide semiconductor layer 22. As a result, it is possible to suppress a defective level from being formed on the lower surface of the oxide semiconductor layer 22. Therefore, it is possible to suppress characteristic fluctuation due to the reliability test of the transistor 210B, a decrease in field-effect mobility, or characteristic variation.

### [Method for Manufacturing Semiconductor Device 100B]

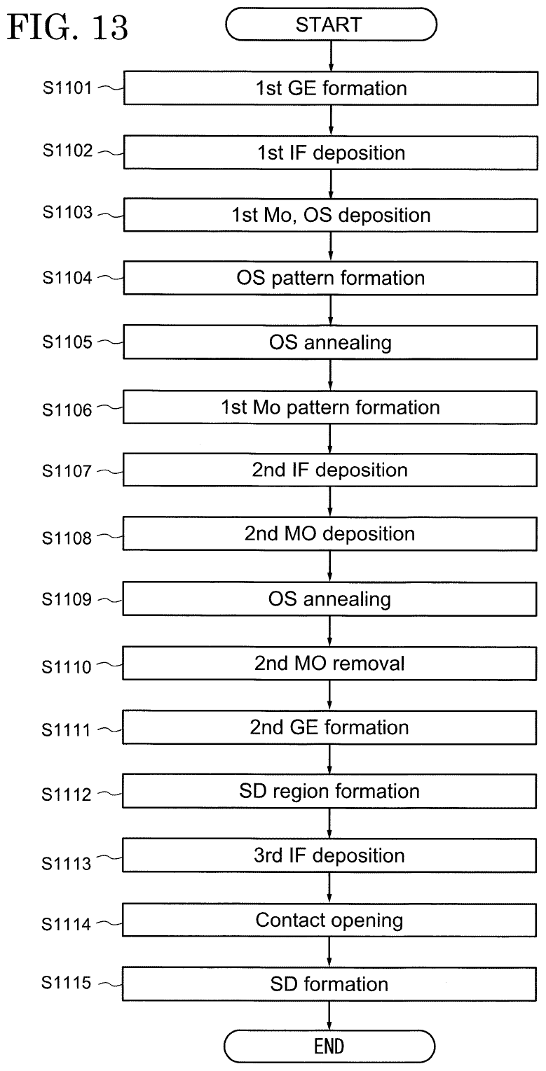

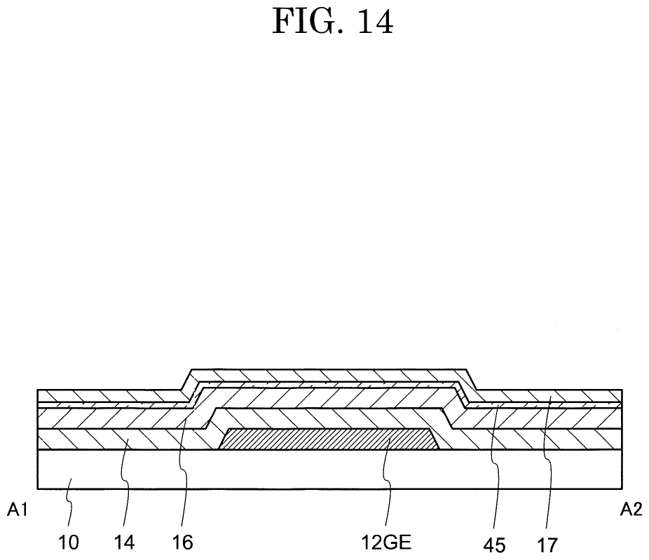

The semiconductor device 100B according to an embodiment of the present invention will be described with reference to FIG. 13. FIG. 13 is a sequence diagram showing the method for manufacturing the semiconductor device 100B according to an embodiment of the present invention. FIG. 14 to FIG. 17 are cross-sectional views showing the method for manufacturing the semiconductor device 100B according to an embodiment of the present invention. In addition, detailed descriptions of the steps similar to those of the first embodiment will be omitted.

As shown in FIG. 13, step S1101 to step S1102 are similar to step S1001 to step S1002 shown in FIG. 2.

In the present embodiment, as shown in FIG. 13 and FIG. 14, after the step S1102, a metal oxide film 45 containing aluminum as a main component and the oxide semiconductor film 17 are formed on the first insulating film 16 (“1st MO, OS deposition” in step S1103 shown in FIG. 13).

The metal oxide film 45 is deposited by the sputtering method or the atomic layer deposition method. For example, the thickness of the metal oxide film 45 is 1 nm or more and 50 nm or less, 1 nm or more and 30 nm or less, 1 nm or more and 20 nm or less, or 1 nm or more and 10 nm or less. In the present embodiment, aluminum oxide is used as the metal oxide film 45. Aluminum oxide has a high barrier property against gases such as oxygen or hydrogen. In the present embodiment, the aluminum oxide used as the metal oxide film 45 blocks hydrogen and oxygen released from the first insulating film 16, and suppresses the released hydrogen and oxygen from reaching the oxide semiconductor layer 22 formed later.

The deposition method and material of the oxide semiconductor film 17 in the present embodiment may be referred to the description of the deposition method and material of the oxide semiconductor film 17 (“OS deposition” in step S1003 shown in FIG. 2).

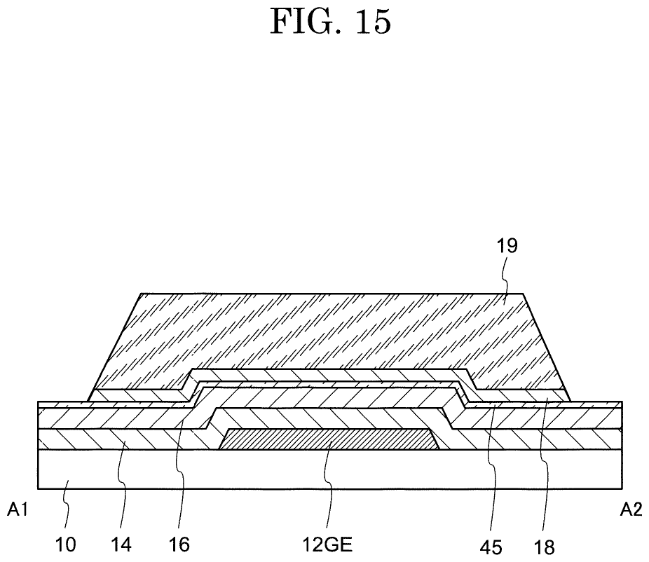

As shown in FIG. 13 and FIG. 15, a pattern of the oxide semiconductor layer 18 is formed (“1st OS pattern formation” in step S1104 shown in FIG. 13). The resist mask 19 is formed on the oxide semiconductor film 17, and the oxide semiconductor film 17 is etched using the resist mask 19. The etching method of the oxide semiconductor film 17 in the present embodiment may be referred to the description of the etching method of the oxide semiconductor film 17 (“OS pattern formation” in step S1004 shown in FIG. 2).

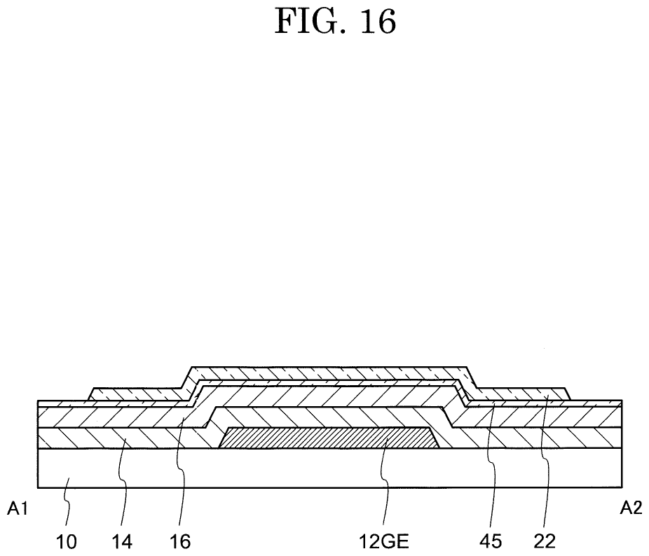

As shown in FIG. 13 and FIG. 16, the pattern of the oxide semiconductor layer 18 is formed, and then the heat treatment (OS annealing) is performed on the oxide semiconductor layer 18 (“OS annealing” in step S1105 shown in FIG. 13). Conditions for OS annealing may be referred to the explanation of the conditions for the oxide semiconductor layer 18 (“OS annealing” in step S1005 shown in FIG. 3). By performing OS annealing, the oxide semiconductor layer 18 is crystallized, and the oxide semiconductor layer 22 having a polycrystalline structure is formed.

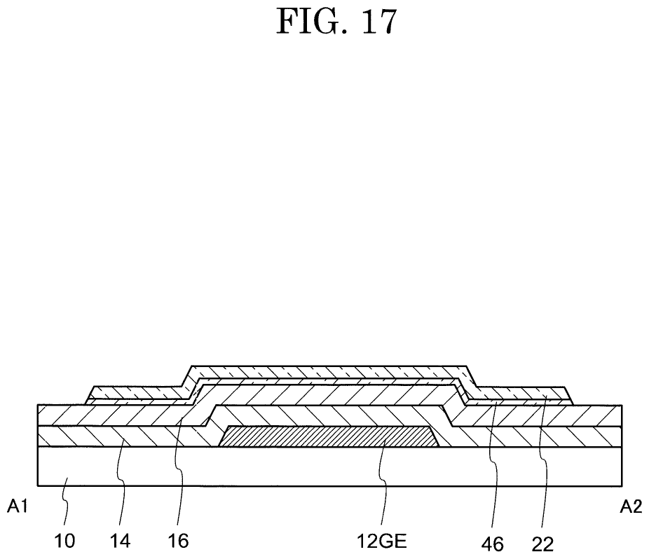

As shown in FIG. 13 and FIG. 17, the metal oxide film 45 is patterned to form the metal oxide layer 46 (“MO pattern formation” in step S1106 shown in FIG. 13). The oxide semiconductor layer 22 sufficiently crystallized by the heat treatment has etching resistance. Therefore, it is possible to suppress the oxide semiconductor layer 22 from disappearing when the metal oxide film 45 is patterned using the crystallized oxide semiconductor layer 22 as a mask. The metal oxide film 45 is etched using the oxide semiconductor layer 22 patterned in the above-described process as a mask. Wet etching may be used, or dry etching may be used as the etching of the metal oxide film 45. For example, dilute hydrofluoric acid (DHF) is used as the wet etching. Since the metal oxide film 45 is etched using the oxide semiconductor layer 22 as a mask, a photolithography process can be omitted.

After that, since step S1107 to step S1108 shown in FIG. 13 are similar to step S1006 to step S1007 shown in FIG. 3, detailed explanations thereof will be omitted.

As shown in FIG. 13, with the second S1109 24 and the metal oxide film 25 formed on the oxide semiconductor layer 22, heat treatment (oxidation annealing) for supplying oxygen from the second insulating film 24 to the oxide semiconductor layer 22 is performed (“Oxidation annealing” in step S1109 shown in FIG. 13).

In the present embodiment, the metal oxide layer 46 is provided below the oxide semiconductor layer 22. When the oxidation annealing is performed in this state, the oxygen released from the first insulating film 16 is blocked by the metal oxide layer 46, so that the oxygen is less likely to be supplied to the lower surface of the oxide semiconductor layer 22. The oxygen released from the first insulating film 16 diffuses from the region where the metal oxide layer 46 is not formed to the second insulating film 24 provided on the first insulating film 16, and reaches the oxide semiconductor layer 22 via the second insulating film 24. As a result, the oxygen released from the first insulating film 16 is less likely to be supplied to the lower surface of the oxide semiconductor layer 22, and is mainly supplied to the side surface and the upper surface of the oxide semiconductor layer 22. In addition, the oxygen released from the second insulating film 24 is supplied to the upper surface and the side surface of the oxide semiconductor layer 22 by the oxidation annealing. Hydrogen may be released from the first insulating films 14 and 16 by the oxidation annealing, but the hydrogen is blocked by the metal oxide layer 46.

As described above, by the oxidation annealing step, oxygen can be supplied to the upper surface and the side surface of the oxide semiconductor layer 22 having many oxygen defects while suppressing the supply of oxygen to the lower surface of the oxide semiconductor layer 22 having few oxygen defects.

After that, step 1110 to step 1115 shown in FIG. 13 are similar to step S1009 to step S1014 shown in FIG. 3.

Through the above steps, the semiconductor device 100B shown in FIG. 12 can be manufactured.

In the semiconductor device 100B manufactured by the above-described manufacturing method, oxygen defects contained in the oxide semiconductor layer 22 can be further reduced as compared with the method for manufacturing the semiconductor device 100 described in the first embodiment. Therefore, in the semiconductor device 100B described in the present embodiment, electrical characteristics having a mobility of 50 cm²/Vs or more, 55 cm²/Vs or more, or 60 cm²/Vs or more can be obtained in a range where the channel length L1 of the channel region CH of the transistor 210B is 2 μm or more and 4 μm or less and the channel width W of the channel region CH is 2 μm or more and 25 μm or less.

Further, it is possible to suppress excessive oxygenation from being supplied to the lower surface of the oxide semiconductor layer 22. In particular, since the oxygen defects contained in the channel region CH are sufficiently reduced, it is possible to suppress hydrogen from being trapped in the oxygen defects. As a result, since the characteristic fluctuation due to the reliability test of the transistor 210B can be further reduced, the reliability of the semiconductor device 100B is improved.

### Third Embodiment

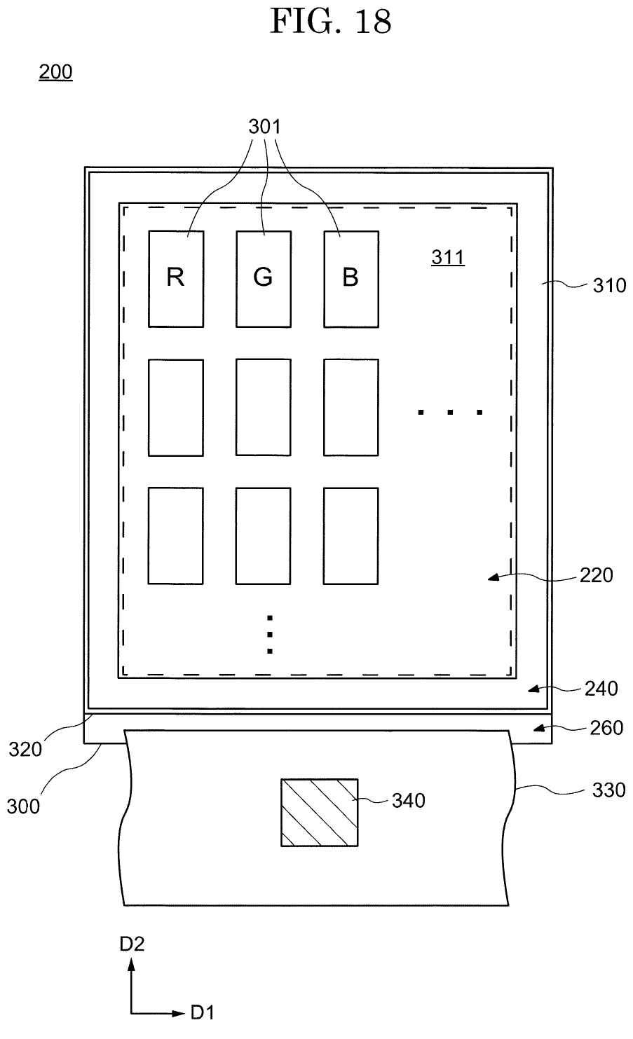

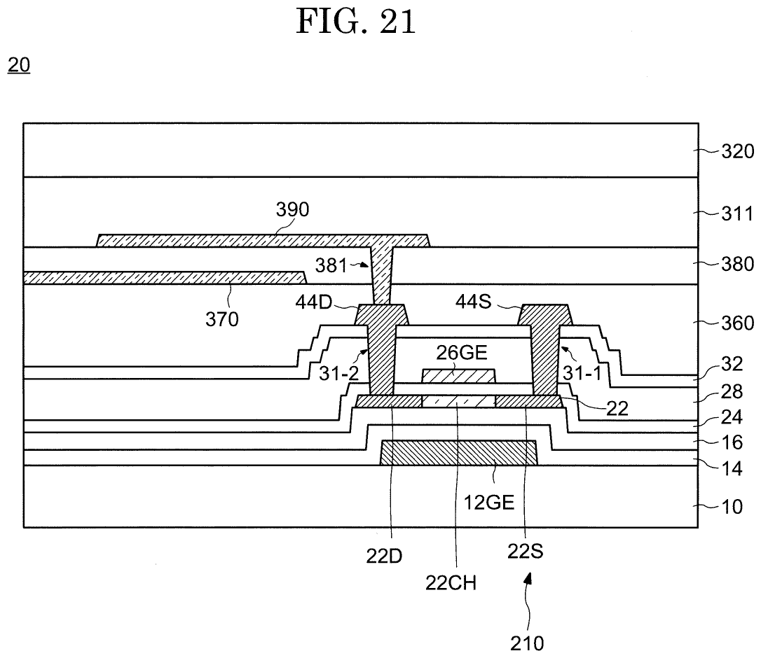

A display device 200 using the semiconductor device 100 according to an embodiment of the present invention will be described with reference to FIG. 18 to FIG. 24. In the embodiment described below, a configuration in which the semiconductor device 100 described in the first embodiment is applied to a circuit of a liquid crystal display device will be described.

### [Overview of Display Device 200]

FIG. 18 is a plan view showing an overview of the display device 200 according to an embodiment of the present invention. As shown in FIG. 18, the display device 200 includes an array substrate 300, a seal portion 310, a counter substrate 320, a flexible printed circuit board (also referred to as an FPC 330 in the following explanation), and an IC chip 340. The array substrate 300 and the counter substrate 320 are bonded together by the seal portion 310. A plurality of pixel circuits 301 is arranged in a matrix in a liquid crystal region 220 surrounded by the seal portion 310. The liquid crystal region 220 is a region that overlaps a liquid crystal element 311 described later in a plan view.

A seal region 240 where the seal portion 310 is provided is a region around the liquid crystal region 220. The FPC 330 is provided in a terminal region 260. The terminal region 260 is a region where the array substrate 300 is exposed from the counter substrate 320 and is provided outside the seal region 240. The outside of the seal region 240 means the outside of the region where the seal portion 310 is provided and the region surrounded by the seal portion 310. The IC chip 340 is provided on the FPC 330. The IC chip 340 supplies a signal for driving each pixel circuit 301.

### [Circuit Configuration of Display Device 200]

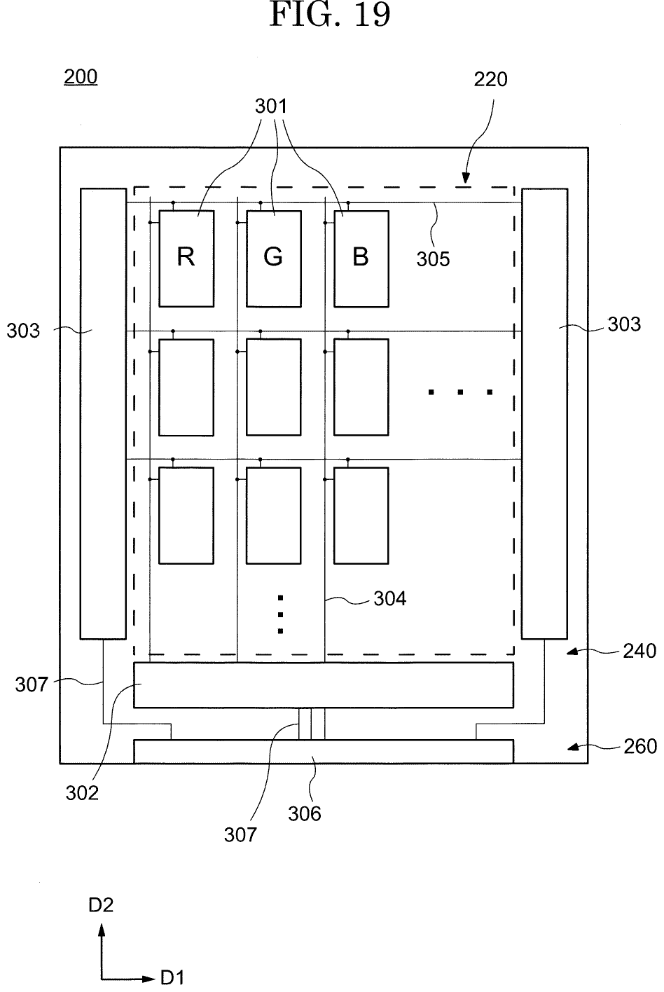

FIG. 19 is a diagram showing a configuration of the display device 200 according to an embodiment of the present invention. As shown in FIG. 19, a source driver circuit 302 is provided at a position adjacent to the liquid crystal region 220 on which the pixel circuit 301 is provided in the second direction D2 (column direction), and a gate driver circuit 303 is provided at a position adjacent to the liquid crystal region 220 in the first direction D1 (row direction). The source driver circuit 302 and the gate driver circuit 303 are provided in the seal region 240. However, the region where the source driver circuit 302 and the gate driver circuit 303 are provided is not limited to the seal region 240, and may be any region outside the region where the pixel circuit 301 is provided.

A source wiring 304 extends from the source driver circuit 302 in the second direction D2 and is connected to the plurality of pixel circuits 301 arranged in the second direction D2. The second gate electrode 26GE extends from the gate driver circuit 303 in the first direction D1 and is connected to the plurality of pixel circuits 301 arranged in the first direction D1.

The terminal section 306 is provided in the terminal region 260 is provided. The terminal section 306 and the source driver circuit 302 are connected by a connection wiring 307. Similarly, the terminal section 306 and the gate driver circuit 303 are connected by the connection wiring 307. When the FPC 330 is connected to the terminal section 306, an external device to which the FPC 330 is connected is connected to the display device 200, and each pixel circuit 301 provided in the display device 200 is driven by a signal from the external device.

The transistors 210, 210A, and 210B shown in the first embodiment and the second embodiment are used as transistors included in the pixel circuit 301, the source driver circuit 302, and the gate driver circuit 303.

### [Pixel Circuit 301 of Display Device 200]

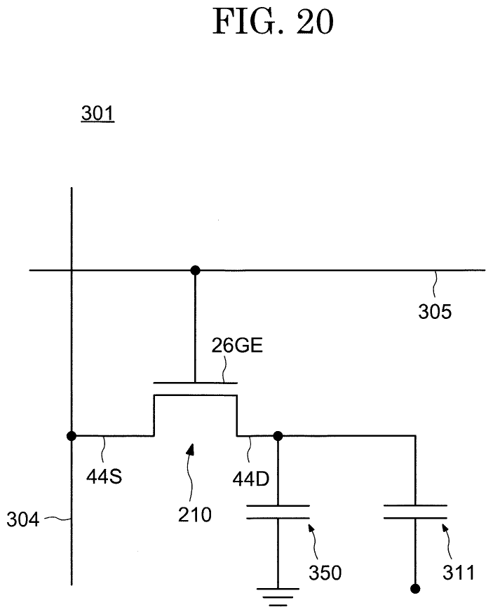

FIG. 20 is a circuit diagram showing a pixel circuit of the display device 200 according to an embodiment of the present invention. As shown in FIG. 20, the pixel circuit 301 includes elements such as the semiconductor device 100, a storage capacitor 350, and the liquid crystal element 311. The semiconductor device 100 includes the second gate electrode 26GE, the source electrode 44S, and the drain electrode 44D. The second gate electrode 26GE is connected to the second gate electrode 26GE. The source electrode 44S is connected to the source wiring 304. The drain electrode 44D is connected to the storage capacitor 350 and the liquid crystal element 311. In the present embodiment, for convenience of explanation, the electrode indicated by the reference sign “44S” may be referred to as a source electrode, and the electrode indicated by the reference sign “44D” may be referred to as a drain electrode, but the electrode indicated by the reference sign “44S” may function as a drain electrode, and the electrode indicated by the reference sign “44D” may function as a source electrode.

### [Configuration of Display Device 200]

FIG. 20 is a cross-sectional view of the display device 200 according to an embodiment of the present invention. As shown in FIG. 20, the display device 200 is a display device to which the semiconductor device 100 is applied.

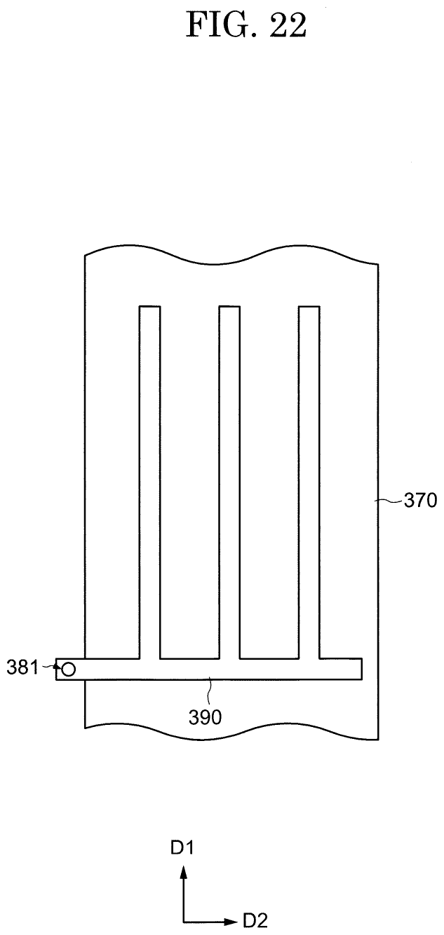

As shown in FIG. 20 and FIG. 22, the first gate electrode 12GE is provided on the substrate 10. In addition, the oxide semiconductor layer 22 is provided on the first gate electrode 12GE. The second gate electrode 26GE is provided on the oxide semiconductor layer 22. A source wiring and the drain electrode 44D are provided on the second gate electrode 26GE. The source wiring is connected to the source region 22S via the contact hole 31-1. A region of the source wiring connected to the oxide semiconductor layer 22 functions as the source electrode 44S. In addition, the drain electrode 44D is connected to the drain region 22D via the contact hole 31-2.

An insulating film 360 is provided on the source electrode 44S and the drain electrode 44D. A common electrode 370 is commonly provided for a plurality of pixels on the insulating film 360. An insulating film 380 is provided on the common electrode 370. An opening 381 is provided in the insulating films 360 and 380. A pixel electrode 390 is provided on the insulating film 380 and inside the opening 381. The pixel electrode 390 is connected to the drain electrode 44D.

FIG. 22 is a plan view of the pixel electrode 390 and the common electrode 370 of the display device 200 according to an embodiment of the present invention. As shown in FIG. 22, the common electrode 370 has an overlapping region that overlaps the pixel electrode 390 in a plan view, and a non-overlapping region that does not overlap the pixel electrode 390. When a voltage is supplied between the pixel electrode 390 and the common electrode 370, a lateral electric field is formed from the pixel electrode 390 in the overlapping region toward the common electrode 370 in the non-overlapping region. When liquid crystal molecules contained in the liquid crystal element 311 are operated by the lateral electric field, a gradation of the pixel is determined.

Although a configuration in which the semiconductor device 100 is used for the pixel circuit 301 is exemplified in the present embodiment, the semiconductor device 100 may be used for a peripheral circuit including the source driver circuit 302 and the gate driver circuit 303.

### Fourth Embodiment

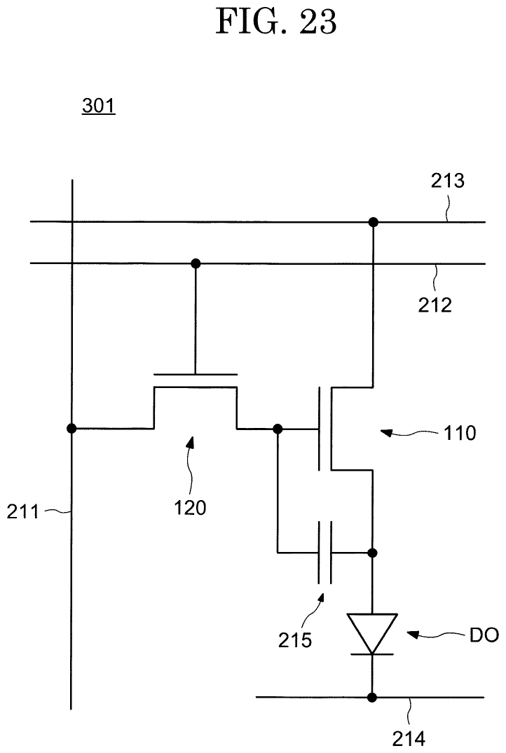

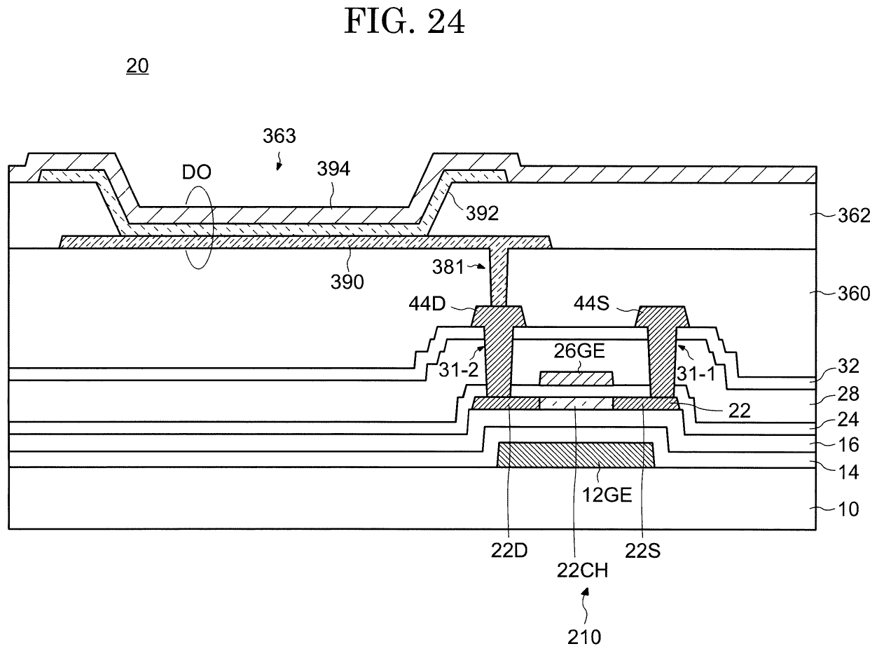

The display device 200 using the semiconductor device 100 according to an embodiment of the present invention will be described with reference to FIG. 23 and FIG. 24. In the present embodiment, a configuration in which the semiconductor device 100 described in the first embodiment is applied to a circuit of an organic EL display device will be described. Since the overview and the circuit configuration of the display device 200 are similar to those shown in FIG. 23 and FIG. 24, the explanation thereof will be omitted.

### [Pixel Circuit 301 of Display Device 200]

FIG. 23 is a circuit diagram showing a pixel circuit of the display device 200 according to an embodiment of the present invention. As shown in FIG. 23, the pixel circuit 301 includes elements such as a driving transistor 110, a selection transistor 120, a storage capacitor 215, and a light-emitting element DO. The driving transistor 110 and the selection transistor 120 have the configuration similar to the transistor 210 of the semiconductor device 100. A source electrode of the selection transistor 120 is connected to a signal line 211, and a gate electrode of the selection transistor 120 is connected to a gate line 212. A source electrode of the driving transistor 110 is connected to an anode power supply line 213, and a drain electrode of the driving transistor 110 is connected to one end of the light-emitting element DO. The other end of the light-emitting element DO is connected to a cathode power supply line 214. A gate electrode of the driving transistor 110 is connected to a drain electrode of the selection transistor 120. The storage capacitor 215 is connected to the gate electrode and the drain electrode of the driving transistor 110. A gradation signal that determines the emission intensity of the light-emitting element DO is supplied to the signal line 211. A signal that selects a pixel row to which the gradation signal is written is supplied to the gate line 212.

### [Cross-sectional Structure of Display Device 200]

FIG. 24 is a cross-sectional view of the display device 200 according to an embodiment of the present invention. The configuration of the display device 200 shown in FIG. 24 is similar to that of the display device 200 shown in FIG. 20, but the structure above the insulating film 360 of the display device 200 in FIG. 24 is different from the structure above the insulating film 360 of the display device 200 in FIG. 20. Hereinafter, among the configurations of the display device 200 shown in FIG. 24, the explanation of configurations similar to those of the display device 200 shown in FIG. 20 will be omitted, and differences will be described.

As shown in FIG. 24, the display device 200 has the pixel electrode 390, a light-emitting layer 392, and a common electrode 394 (the light-emitting element DO) above the insulating film 360. The pixel electrode 390 is provided on the insulating film 360 and inside the opening 381. An insulating film 362 is provided on the pixel electrode 390. An opening 363 is provided in the insulating film 362. The opening 363 corresponds to a light-emitting region. That is, the insulating film 362 defines a pixel. The light-emitting layer 392 and the common electrode 394 are provided on the pixel electrode 390 exposed by the opening 363. The pixel electrode 390 and the light-emitting layer 392 are provided separately for each pixel. On the other hand, the common electrode 394 is commonly provided for a plurality of pixels. The light-emitting layer 392 is made of a material that varies depending on the display color of the pixel.

Although the configuration in which the semiconductor device 100 described in the first embodiment is applied to the liquid crystal display device and the organic EL display device has been exemplified in the third embodiment and the fourth embodiment, the semiconductor device may be applied to a display device (for example, a self-luminous display device or an electronic paper display device other than the organic EL display device) other than the display devices. In addition, the semiconductor device 100 can be applied to a medium-sized display device to a large-sized display device without any particular limitation.

### EXAMPLES

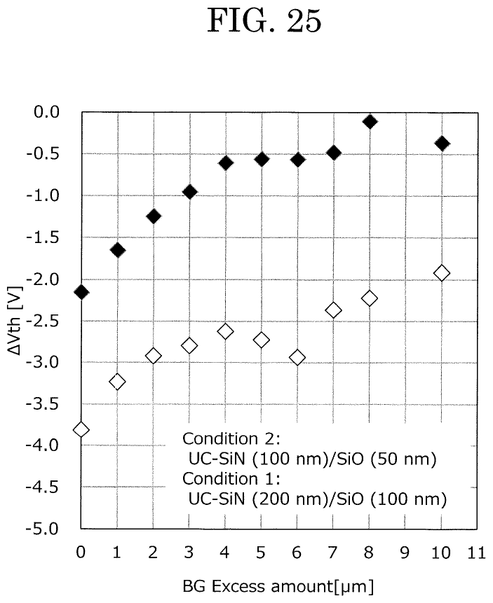

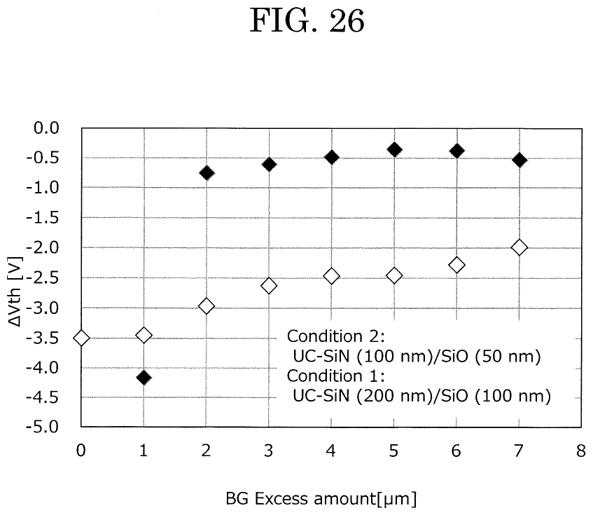

In the present embodiment, whether the degradation of the transistor is caused by the difference between the shape of the top gate and the shape of the bottom gate in the NBTIS test will be described with reference to FIG. 25 to FIG. 26. In the present embodiment, the case where the width of the top gate is fixed and the length L2 in the first region where the bottom gate protrudes from the top gate in the first direction D1 is conditionally swung as the measurement condition 1, and the case where the width of the top gate is fixed and the length L3 in the second region where the bottom gate protrudes from the oxide semiconductor layer in the second direction D2 is conditionally swung as the measurement condition 2 will be described.

[Structure of Transistor under Measurement Condition 1]

The configuration of the transistor used in the measurement condition 1 corresponds to the configuration of the transistor 210 shown in FIG. 1 and FIG. 2. An oxide semiconductor having a polycrystalline structure was used as the oxide semiconductor layer 22. In the following explanation, the bottom gate corresponds to the first gate electrode, and the top gate corresponds to the second gate electrode. Further, in FIG. 2, the channel length L1 of the channel region 22CH was set to 3 μm and the channel width W was set to 4.5 μm. Further, it was checked whether the properties of the transistor 210 were changed depending on the thicknesses of the first insulating films 14 and 16 and the second insulating film 24 under the measurement condition 1. In this case, two types of thickness conditions were applied. For the thickness condition 1, a stacked layer of a 200 nm silicon nitride film and a 100 nm silicon oxide film was used as the first insulating films 14 and 16, and a 100 nm silicon oxide film was used as the second insulating film 24. For the thickness condition 2, a stacked layer of a 100 nm silicon nitride film and a 50 nm silicon oxide film was used as the first insulating films 14 and 16, and a 75 nm silicon oxide film was used as the second insulating film 24. In each of the two thickness conditions, the length L2 in which the first gate electrode 12GE protrudes from the second gate electrode 26GE in the first direction D1 was conditioned to be ±0 μm, 1 μm, 2 μm, 3 μm, 4 μm, 5 μm, 6 μm, 7 μm, 8 μm, and 10 μm. In this case, the length L2 is a design value.

### [Conditions for NBTIS Reliability Test]

Conditions for the NBTIS reliability test are as follows.
Light irradiation condition: With irradiation (7000 lx)
Voltage applied to the first gate electrode: −60 V
Voltage applied to the second gate electrode: −20 V
Voltage applied to the source electrode and the drain electrode: 0 V
Stage temperature during stress application: 85° C., darkroom
Irradiation time: 1000 sec

The measurement conditions of the electrical characteristics of the transistor before and after the stress application are as follows.
Source-drain voltage: 0.1 V, 10 V
Voltage applied to the second gate electrode: −15 V to +15 V
Measurement environment: 85° C., darkroom

Table 1 shows the relationship between the length L2 at which the first gate electrode 12GE protrudes from the second gate electrode 26GE in the first direction D1 and the variation ΔVth in the threshold voltage in the case of the thickness condition 1.

TABLE 1

| L2 [μm] | 0 | 1 | 2 | 3 | 4 | 5 | 6 | 7 | 8 | 10 |
|---|---|---|---|---|---|---|---|---|---|---|
| ΔVth | −3.8 | −3.2 | −2.9 | −2.8 | −2.6 | −2.7 | −2.9 | −2.4 | −2.2 | −1.9 |
| [V] | | | | | | | | | | |

Table 2 shows the relationship between the length L2 at which the first gate electrode 12GE protrudes from the second gate electrode 26GE in the first direction D1 and the variation ΔVth in the threshold voltage in the case of the thickness condition 2.

TABLE 2

| L2 [μm] | 0 | 1 | 2 | 3 | 4 | 5 | 6 | 7 | 8 | 10 |
|---|---|---|---|---|---|---|---|---|---|---|
| ΔVth | −2.2 | −1.7 | −1.2 | −1 | −0.6 | −0.6 | −0.6 | −0.5 | −0.1 | −0.4 |
| [V] | | | | | | | | | | |

A graph representing the reliability test results in Table 1 and Table 2 is shown in FIG. 25. In FIG. 25, the X-axis represents the length L2, and the Y-axis represents the variation in the threshold voltage. Further, in FIG. 25, the white square is the case of the thickness condition 1, and the black square is the thickness condition 2. In the case where the channel length L1 is 3 μm, when the length L2 is the design value of 0 μm to 4 μm (actual value: 3 μm) as shown in FIG. 25, a dependency was confirmed in which the length L2 increases and the variation ΔVth in the threshold voltage decreases. Further, in the design value of 5 μm to 10 μm, even if the length L2 increased, the variation ΔVth in the threshold voltage did not change significantly.

In addition, the variation ΔVth in the threshold voltage under the thickness condition 1 is preferably 3 V or less. Therefore, if the length L2 is at least 2 μm or more, it is considered that variation in the threshold voltage of the transistor can be suppressed under the thickness condition 1. In addition, the variation ΔVth in the threshold voltage is preferably 1 V or less under the thickness condition 2. Therefore, if the length L2 is 3 μm or more, it is considered that the variation in the threshold voltage of the transistor can be suppressed under the thickness condition 2. Further, it was confirmed that the variation in the threshold voltage can be suppressed under the thickness condition 2 rather than the thickness condition 1.

[Configuration of Transistor under Measurement Condition 2]

The configuration of the transistor used in the measurement condition 2 corresponds to the configuration of the transistor 210 shown in FIG. 1 and FIG. 2. An oxide semiconductor layer having a polycrystalline structure was used as the oxide semiconductor layer 22. In the following explanation, the bottom gate corresponds to the first gate electrode 12GE, and the top gate corresponds to the second gate electrode 26GE. Further, in FIG. 2, the channel length L1 of the channel region 22CH was set to 3 μm and the channel width W was set to 4.5 μm. Similar to the measurement condition 1, it was checked whether the properties of the transistor 210 changed depending on the thicknesses of the first insulating films 14 and 16 and the second insulating film 24 under the measurement condition 2. In this case, two types of thickness conditions were applied. For the thickness condition 1, a stacked layer of a 200 nm silicon nitride film and a 100 nm silicon oxide film was used as the first insulating films 14 and 16, and a 100 nm silicon oxide film was used as the second insulating film 24. For the thickness condition 2, a stacked layer of a 100 nm silicon nitride film and a 50 nm silicon oxide film was used as the first insulating films 14 and 16, and a 75 nm silicon oxide film was used as the second insulating film 24. In each of the two thickness conditions, the length L3 in which the first gate electrode 12GE protrudes from the oxide semiconductor layer 22 in the second direction D2 was conditioned to be ±0 μm, 1 μm, 2 μm, 3 μm, 4 μm, 5 μm, 6 μm, and 7 μm. In this case, the length L3 is a design value.

### [Conditions for NBTIS Reliability Test]

Conditions for the NBTIS reliability test are as follows.
Light irradiation condition: With irradiation (7000 lx)
Voltage applied to the first gate electrode: −60 V
Voltage applied to the second gate electrode: −20 V
Voltage applied to the source electrode and the drain electrode: 0 V
Stage temperature during stress application: 85° C., darkroom
Irradiation time: 1000 sec

The measurement conditions of the electrical characteristics of the transistor before and after the stress application are as follows.
Source-drain voltage: 0.1 V, 10 V
Voltage applied to the second gate electrode: −15 V to +15 V
Measurement environment: 85° C., darkroom

Table 3 shows the relationship between the length L3 at which the first gate electrode 12GE protrudes from the oxide semiconductor layer 22 in the second direction D2 and the variation ΔVth in the threshold voltage in the case of the thickness condition 1.

TABLE 3

| L3 [μm] | 0 | 1 | 2 | 3 | 4 | 5 | 6 | 7 |
|---|---|---|---|---|---|---|---|---|
| ΔVth | −3.5 | −3.4 | −3 | −2.6 | −2.5 | −2.5 | −2.3 | −2 |
| [V] | | | | | | | | |

Table 4 shows the relationship between the length L3 at which the first gate electrode 12GE protrudes from the oxide semiconductor layer 22 in the second direction D2 and the variation ΔVth in the threshold voltage in the case of the thickness condition 2.

TABLE 4

| L3 [μm] | 0 | 1 | 2 | 3 | 4 | 5 | 6 | 7 |
|---|---|---|---|---|---|---|---|---|
| ΔVth | −8.6 | −4.2 | −0.8 | −0.6 | −0.5 | −0.4 | −0.4 | −0.5 |
| [V] | | | | | | | | |

A graph representing the reliability test results in Table 3 and Table 4 is shown in FIG. 26. In FIG. 26, the X-axis represents the length L3, and the Y-axis represents the variation in the threshold voltage. Further, in FIG. 26, the white square is the case of the thickness condition 1, and the black square is the thickness condition 2. In the case where the channel length L1 is 3 μm, when the length L3 is the design value 0 μm to 1 μm as shown in FIG. 26, due to the misalignment between the end portion of the oxide semiconductor layer and the end portion of the first gate electrode, the variation ΔVth in the threshold value voltage exceeded 3.0 V. In the case where the design value of the length L3 is larger than 2 μm (actual value: 1 μm), even if the length L3 increased, the variation ΔVth in the threshold voltage did not change significantly.

In addition, the variation ΔVth in the threshold voltage under the thickness condition 1 is preferably 3 V or less. Therefore, if the length L3 is greater than at least 0, including the misalignment between the end portion of the oxide semiconductor layer and the end portion of the first gate electrode, it is considered that variation in the threshold voltage of the transistor can be suppressed. In addition, the variation ΔVth in the threshold voltage in the thickness condition 2 is preferably 1 V or less. Therefore, in the thickness condition 2, if the length L3 is 2 μm or more including the misalignment between the end portion of the oxide semiconductor layer and the end portion of the first gate electrode, it is considered that the variation in the threshold voltage of the transistor can be suppressed.

Each of the embodiments described above as an embodiment of the present invention can be appropriately combined and implemented as long as no contradiction is caused. Further, the addition, deletion, or design change of components, or the addition, deletion, or condition change of processes as appropriate by those skilled in the art based on each embodiment are also included in the scope of the present invention as long as they are provided with the gist of the present invention.

Further, it is understood that, even if the effect is different from those provided by each of the above-described embodiments, the effect obvious from the description in the specification or easily predicted by persons ordinarily skilled in the art is apparently derived from the present invention.

What is claimed is:

1. A semiconductor device including a transistor, the transistor comprising:
a first gate electrode;
a first gate insulating film provided on the first gate electrode;
an oxide semiconductor layer provided on the first gate insulating film, overlapping the first gate electrode, and having a polycrystalline structure;
a second gate insulating film provided on the oxide semiconductor layer; and
a second gate electrode provided on the second gate insulating film and overlapping the first gate electrode,
wherein the first gate electrode has a first region and a second region,
the first region overlaps the oxide semiconductor layer and protrudes in a first direction from the second gate electrode in a plan view, and
the second region overlaps the second gate electrode and protrudes in a second direction that intersects the first direction from the oxide semiconductor layer in a plan view.

2. The semiconductor device according to claim 1, wherein
the transistor further includes a source electrode and a drain electrode provided on the second gate electrode and connected to the oxide semiconductor layer, and
wherein a first length from the second gate electrode to the source electrode in the first direction in the oxide semiconductor layer is longer than a second length in the first direction in the first region.

3. The semiconductor device according to claim 1, wherein
the first direction is the same direction as a channel length of the transistor, and the second direction is the same direction as a channel width of the transistor.

4. The semiconductor device according to claim 3, wherein
the second length is 2 μm or more.

5. The semiconductor device according to claim 3, wherein
a third length in the second direction in the second region is greater than zero.

6. The semiconductor device according to claim 1, wherein
the first gate insulating film is stacked with a silicon nitride film and a silicon oxide film, and
a thickness of the first gate insulating film is 150 nm or more and 300 nm or less.

7. The semiconductor device according to claim 1, wherein
the first gate insulating film and the oxide semiconductor layer are further provided with a first metal oxide layer.
